(19) United States
(12) Patent Application Publication
(10) Pub. No.: US 2006/0086937 A1
(43) Pub. Date: Apr. 27, 2006

(54) Tft array substrate, liquid crystal display device, manufacturing methods of tft array substrate and liquid crystal display device, and electronic device

(76) Inventors: Akiyoshi Fujii, Nara-shi Nara (JP); Takaya Nakabayashi, Iga-shi Mie (JP); Hisao Ochi, Tenri-shi Nara (JP); Takaeshi Hara, Ikoma-gun Nara (JP); Yuhichi Saitoh, Tenri-shi Nara (JP)

Correspondence Address: BIRCH STEWART KOLASCH & BIRCH, PO BOX 747, FALLS CHURCH, VA, 22040-0747, US

(21) Appl. No.: 10/526,009

(22) PCT Filed: Aug. 29, 2003
(86) PCT No.: PCT/JP03/11057

§ 371 Date: Feb. 25, 2005

(51) Int. Cl. H01L 29/04

(52) U.S. Cl. 257/72

(57) ABSTRACT

A TFT array substrate includes a thin film transistor section in which a gate electrode is formed on a substrate, and a semiconductor layer is formed on the gate electrode via a gate insulation layer. The semiconductor layer of this TFT array substrate has a shape formed by dropping a droplet. Accordingly, it is possible to directly forming a semiconductor layer, or a resist layer for forming the semiconductor layer, by dropping a droplet(s). On this account, the present invention allows the use of an inkjet method, thus reducing costs and numbers of manufacturing processes.

### TECHNICAL FIELD

The present invention relates to a TFT array substrate; a liquid crystal display device; manufacturing methods of the TFT array substrate and the liquid crystal display device; and an electronic device.

### BACKGROUND ART

Conventionally, for a liquid crystal display device including a TFT (Thin Film Transistor), a TFT array substrate is manufactured through a series of manufacturing steps, as shown in FIG. 28. More specifically, the manufacturing method of a conventional TFT array substrate is carried out through the steps of depositing a material for gate line, forming the gate line, depositing a gate insulation layer and depositing a semiconductor layer, forming the semiconductor layer, depositing a material for source line and drain line, forming the source line and the drain line, processing a channel section, which exists between the source and the drain electrode on the semiconductor layer, forming a passivation film, processing the passivation film, depositing a pixel electrode, and forming the pixel electrode (101 through 111).

Among these steps, the gate line forming step 102, the semiconductor layer forming step 104, the source/drain lines forming step 106, the passivation film processing step 109, and the pixel electrode forming step 111, which involves photolithography and etching performed with a mask. More specifically, these steps use photolithography and etching so as to process the film formed through the previous steps, i.e., the gate line depositing step 101, the gate insulation layer/semiconductor layer depositing step 103, the source/drain lines depositing step 105, the passivation film forming step 108, and the pixel electrode depositing step 110.

Meanwhile, there has been a technique proposed in recent years, which forms wiring by an inkjet method without using photolithography. In this technique, the substrate is provided with two areas respectively having an affinity characteristic and a non-affinity characteristic with respect to a liquid material of the wiring, in a surface to which the wiring will be formed; and the liquid of the wiring material is dropped by an inkjet method onto the affinity area so as to form the wiring. Hereinafter, the areas having an affinity characteristic and a non-affinity characteristic with respect to a general liquid including a liquid wiring material are referred to as a lyophilic area and a lyophobic area, respectively; and the areas having an affinity characteristic and a non-affinity characteristic with respect to an aqueous liquid are referred to as a hydrophilic area and a hydrophobic area, respectively. Such a technique is disclosed in a Document 1 (Japanese Laid-Open Patent Application Tokukaihei 11-204529/1999 (published on Jul. 30, 1999)).

Further, another wiring forming technique using an inkjet method is disclosed in a Document 2 (Japanese Laid-Open Patent Application Tokukai 2000-353594/2000 (published on Dec. 19, 2000)). In this method, the wiring forming area is provided with banks on the respective ends so as to keep the wiring material within the area. In this technique, the upper portion of the bank is lyophobic, and the wiring forming area is lyophilic.

Further, still another wiring forming technique using an inkjet method is disclosed in a Document 3 (SID 01 DIGEST 2001, Page 40 to 43, 6.1: Invited Paper: All-Polymer Thin Film Transistors Fabricated by High-Resolution Inkjet Printing (by Takeo Kawase and other writers) in which a TFT is formed only by organic materials.

As described, the conventional manufacturing method of a TFT array substrate involving photolithography uses masks at least in the following five steps: the gate line forming step 102, the semiconductor layer forming step 104, the source/drain lines forming step 106, the passivation film processing step 109, and the pixel electrode forming step 111.

Further, the conventional method uses vacuum equipments in the respective deposition steps, and also in the respective processing steps (forming and processing steps) after the deposition. Accordingly, in order to meet the recent market demand for a larger liquid crystal display device, the conventional method consumes enormous cost, as the TFTs are formed by such a manner with respect to a large-sized substrate.

Furthermore, the demand for a larger substrate brings about greater consumption of resists or wiring material. Meanwhile, the materials (such as a resist) used in the processing steps for forming the wiring etc., are removed and discarded by etching or removing, since an effective reusing method of those has not yet been realized. Accordingly, works and costs for the discard are growing bigger with the demand for a larger substrate, as well as environmental burden due to the discarded material. As described, the conventional manufacturing method of a TFT array substrate, which mainly involves photolithography, requires more manufacturing steps and a greater cost.

On the other hand, as disclosed in the foregoing Documents, the manufacturing method of a TFT array substrate using an inkjet method requires less number of masks. Therefore, there has been a demand for development of the inkjet method as a technique for realizing reduction in both manufacturing steps and costs.

### DISCLOSURE OF INVENTION

A TFT array substrate according to the present invention includes: a thin film transistor section in which a gate electrode is formed on a substrate, and a semiconductor layer is formed on the gate electrode via a gate insulation layer, the semiconductor layer having a shape formed by dropping a droplet.

With this arrangement, since the semiconductor layer has a shape of a dropped droplet(s) (substantially a circular shape, or a shape made of plural overlapped circles, for example), the semiconductor layer can be formed by dropping a droplet(s) of a semiconductor material by using an inkjet method. Alternatively, the semiconductor layer may be formed in such a manner that a resist layer is formed by dropping a droplet(s) of a resist material onto a semiconductor film by an inkjet method, and the resist layer is used as a mask for processing a semiconductor film. Further, the resist material may instead be a conductive material, and a conductor forming layer may be formed by dropping the droplet(s) of the conductive material by an inkjet method so as to be used as a mask for forming the semiconductor layer.

With this method, it is possible to manufacture the TFT array substrate without a mask for forming a semiconductor layer. Accordingly, the required number of masks in the manufacturing is reduced, thus reducing manufacturing processes. Further, the manufacturing requires less photolithography processes using a mask, thus reducing equipment outlay for the photolithography. On this account, it is possible to reduce the time and costs of manufacturing.

Note that, in addition to the foregoing inkjet method, the dropping of the droplet of a semiconductor material, a resist material or a conductive material can be carried out by any methods enabling direct formation of the semiconductor layer, the resist layer or the conductor forming layer, by dropping a droplet(s).

A manufacturing method of a TFT array substrate according to the present invention includes the steps of: (a) forming a gate electrode on a substrate; (b) forming a gate insulation layer on the gate electrode; (c) depositing a semiconductor film on the gate insulation layer; (d) forming a resist layer having a shape of a droplet by dropping a droplet of a resist material on the semiconductor film; and (e) removing the resist layer, after processing the semiconductor film corresponding to the shape of the resist layer so as to create a semiconductor layer of a thin film transistor section.

In this manner, a resist layer is formed on a deposited semiconductor film by dropping a droplet of a resist material, and the semiconductor layer is formed by using this resist layer having the shape of the droplet (normally a circular shape) as a mask.

With this method, it is possible to manufacture the TFT array substrate without a mask for forming a semiconductor layer. Accordingly, the required number of masks in the manufacturing is reduced, thus reducing manufacturing processes. Further, the manufacturing requires less photolithography processes using a mask, thus reducing equipment outlay for the photolithography. On this account, it is possible to reduce the time and costs of manufacturing.

Note that, in addition to the foregoing inkjet method, the dropping of the droplet of a resist material can be carried out by any methods enabling direct formation of the resist layer by dropping a droplet(s).

A manufacturing method of a TFT array substrate according to the present invention includes the steps of: (a) forming a gate electrode with a branch electrode on a substrate; (b) forming a gate insulation layer on the gate electrode; and (c) forming a semiconductor layer having a shape of a droplet as a semiconductor layer of a thin film transistor section, by dropping a droplet of a semiconductor material on the gate insulation layer on the branch electrode.

In this manner, the semiconductor layer is formed in a shape of a droplet (normally a circular shape) by only dropping a droplet of a semiconductor material on the gate insulation layer of the branch electrode.

With this method, it is possible to manufacture the TFT array substrate without a mask for forming a semiconductor layer. Accordingly, the required number of masks in the manufacturing is reduced, thus reducing manufacturing processes. Further, the manufacturing requires less photolithography processes using a mask, thus reducing equipment outlay for the photolithography. On this account, it is possible to reduce the time and costs of manufacturing, and to effectively use the materials.

Note that, in addition to the foregoing inkjet method, the dropping of the droplet of a semiconductor material can be carried out by any methods enabling direct formation of the semiconductor layer by dropping a droplet(s).

A manufacturing method of a TFT array substrate according to the present invention includes the steps of: (a) forming a gate electrode on a substrate; (b) forming a gate insulation layer on the gate electrode; (c) forming a semiconductor layer of a thin film transistor section on the gate insulation layer; (d) forming a first area to which a source electrode is formed, and a second area to which at least a pixel electrode is formed, by dropping a droplet of an electrode material on the substrate after subjected to the step (c); and (e) forming a source electrode, a drain electrode, and a pixel electrode in the first and the second areas by dropping droplets of an electrode material on the substrate after subjected to the step (d).

In this manner, the first area to which a source electrode is formed by dropping a droplet of an electrode material, and the second area to which at least a pixel electrode is formed by dropping a droplet of an electrode material are formed in one process for pre-processing of the electrode forming step. Therefore, the manufacturing processes and costs can be reduced compared to the case of separately forming the first and the second areas in different steps.

A manufacturing method of a liquid crystal display device according to the present invention includes one of the foregoing manufacturing methods of a TFT array substrate. Therefore, it is possible to reduce at least manufacturing processes for producing a liquid crystal display device, thus reducing costs.

A TFT array substrate according to the present invention includes: a thin film transistor section in which a gate electrode is formed on a substrate, and a semiconductor layer and a conductor layer are formed on the gate electrode via a gate insulation layer, wherein: the conductor layer is formed in contact with the semiconductor layer and one of source and drain electrodes of the thin film transistor section, and has a portion formed by dropping a droplet, the conductor layer and the semiconductor layer having substantially the same shape in the portion formed by dropping a droplet.

In this arrangement, a conductor forming layer is formed on a deposited semiconductor film by dropping a droplet of a conductive material, and the semiconductor layer is formed by using this conductor forming layer having the shape of the droplet (normally a circular shape). The conductor forming layer is then processed to be completed as a conductor layer. This conductor forming layer is used as a mask for forming the semiconductor layer, but is not required to be removed unlike the resist layer; therefore, the removal process can be omitted. In this arrangement, the dropping of the droplet of a conductive material onto the semiconductor layer can be carried out by an inkjet method, for example, or by any methods enabling formation of a droplet having an appropriate size for a semiconductor layer of the thin film transistor section.

With this arrangement of a TFT array substrate, the semiconductor layer can be formed without a mask; and therefore the required number of masks is reduced. Further, the conductor forming layer is not required to be removed unlike the resist layer, and therefore the removal process can be omitted, thus greatly reducing manufacturing processes. Further, the manufacturing can be performed with less number of photolithography processes using a mask, thus reducing equipment outlay for photolithography. Moreover, the required amount of chemicals, such as a developer or removing agent can also be reduced, as well as amount of waste of the resist material etc. On this account, it is possible to reduce the time and costs of manufacturing.

Further, the conductor layer may be constituted of Mo, W, Ag, Cr, Ta, Ti, a metal material mainly containing one of Mo, W, Ag, Cr, Ta, Ti, or an indium tin oxide.

Here, the metal material mainly containing one of Mo, W, Ag, Cr, Ta, Ti may be an alloy material, or may be one containing a nonmetallic element, such as N, O, or C. Since the diffusion amount of these materials to the semiconductor layer is small, these material examples of the conductor layer shown here are used as a diffusion preventing layer.

More specifically, with the foregoing arrangement, the conductor layer, provided between the semiconductor layer and the source or drain electrode, operates as a diffusion preventing layer for practically preventing diffusion of a component element(s) constituting the source electrode or the drain electrode. Further, the conductor forming layer, which is a previous state of the conductor layer, also operates as the diffusion preventing layer. Here, practical prevention of diffusion refers to an effect that the diffusion amount of the materials is so small even after heat treatment that there is few practical influence of the diffusion to the semiconductor layer.

With this arrangement, manufacturing processes can be greatly reduced compared to the conventional method for forming a diffusion preventing layer after the semiconductor layer, for example, a method in which the source and drain electrodes are respectively constituted of a diffusion preventing layer and a low electric resistance layer, in this order from the glass substrate.

In recent years, demand for a larger TFT array substrate requires greater low electric resistance of a source or drain electrode, and therefore a source or drain electrode is often made of Al, Cu or the like, which is likely to diffuse into the semiconductor layer when the material is directly in contact with the semiconductor layer. The foregoing configuration of the present invention can deal with such a circumstance. Therefore, the configuration of the present invention has a wider selection range of materials for constituting a source or drain electrode, while hardly increasing the number of manufacturing processes.

In the TFT array substrate according to the present invention having the foregoing configuration, by constituting the conductor layer with the foregoing method, the conductor forming layer as a previous state of the conductor layer operates as a pattern mask for forming the semiconductor layer and also as a diffusion preventing layer for preventing the diffusion into the semiconductor layer. Furthermore, the conductor layer created from the conductor forming layer also has the diffusion preventing function. Accordingly, the manufacturing processes can be greatly reduced when the source electrode etc. is made of a material such as Al, Cu, which tends to diffuse into the semiconductor layer, thus improving productivity of the TFT array substrate.

The source and drain electrodes are preferably made of an Al or a metal material mainly containing Al.

Here, the metal material mainly containing Al may be an Al alloy material, such as an Al—Ti or Al—Nd, or may be one containing a nonmetallic element, such as N, O, or C.

The conductor forming layer of the present invention is divided to be the conductive layers through partial etching using patterns of the source and drain electrodes. This process is necessary to electrically divide the source and drain electrodes of the TFT.

With the foregoing arrangement, it is possible to subject the conductor forming layer to wet-etching while hardly damaging the areas of the source and drain electrodes.

This wet-etching uses a characteristic of an Al or the metal material mainly containing Al, which is not likely to be damaged by an oxidative acid, such as a nitric acid.

Here, the conductor forming layer is preferably made of an Ag, Mo, W, or an alloy mainly containing an Ag, Mo, W, which are soluble by an oxidative acid such as a nitric acid. With this arrangement, the conductor forming layer can be subjected to wet-etching by an oxidative acid, such as a nitric acid with desirable selectivity, thus obtaining the conductor layer without hardly damaging the source electrode etc. made of an Al or the metal material mainly containing Al.

The TFT array substrate according to the present invention having the foregoing configuration includes a low resistance source electrode etc. made of an Al or the metal material mainly containing Al. Therefore the TFT array substrate can be compatible with a recent large-sized TFT array substrate.

The TFT array substrate according to the present invention is exceptionally useful because it has the foregoing configuration with two characteristics: low electrical resistance and appropriateness of manufacturing process which enables etching of the conductor forming layer to create a conductor layer with desirable selectivity.

Note that, in addition to the foregoing inkjet method, the dropping of the droplet of a conductive material can be carried out by any methods enabling direct formation of the conductor forming layer by dropping a droplet(s).

Further, the liquid crystal display device according to the present invention includes the foregoing TFT array substrate. Accordingly, the manufacturing of the liquid crystal display device requires less manufacturing steps of the TFT array substrate, thus reducing the time and costs of manufacturing.

Such a TFT array substrate can be manufactured through the following method, for example.

A manufacturing method of a TFT array substrate according to the present invention includes the steps of: (a) forming a gate electrode on a substrate; (b) forming a gate insulation layer on the gate electrode; (c) depositing a semiconductor film on the gate insulation layer; (d) forming a conductor forming layer having a shape of a droplet by dropping a droplet of a conductive material on the semiconductor film; and (e) forming a semiconductor layer of a thin film transistor section by processing the semiconductor film corresponding to the shape of the conductor forming layer.

In this arrangement, a conductor forming layer is formed on a deposited semiconductor film by dropping a droplet of a conductive material, and the semiconductor layer is formed by using this conductor forming layer having the shape of the droplet (normally a circular shape) as a mask. This conductor forming layer is not required to be removed unlike the resist layer; therefore, the removal process can be omitted.

With this arrangement of a TFT array substrate, the semiconductor layer can be formed without a mask; and therefore the required number of masks is reduced, thus reducing manufacturing processes. Further, the manufacturing can be performed with less number of photolithography processes using a mask, thus reducing equipment outlay for photolithography. Further, the required amount of chemicals, such as a developer or removing agent can also be reduced, as well as amount of waste of the resist material etc. On this account, it is possible to reduce the time and costs of manufacturing.

Note that, in addition to the foregoing inkjet method, the dropping of the droplet of a conductive material can be carried out by any methods enabling direct formation of the conductor forming layer by dropping a droplet(s).

Further, the conductor layer may be constituted of Mo, W, Ag, Cr, Ta, Ti, a metal material mainly containing one of Mo, W, Ag, Cr, Ta, Ti, or an indium tin oxide.

Further, the source and drain electrodes may be made of an Al or a metal material mainly containing Al.

The manufacturing method of a liquid crystal display device according to the present invention includes one of the foregoing manufacturing methods of a TFT array substrate. Therefore, it is possible to reduce at least manufacturing processes for producing a liquid crystal display device.

Further, the TFT array substrate of the present invention is compatible with various electronic devices as well as a liquid crystal display device. The various electronic devices may be some different types of electronic device using a TFT array substrate; for example, a display device such as an organic EL panel or an inorganic EL panel; or a two-dimensional image input device such as a fingerprint sensor or an X-ray imaging device.

Additional objects, features, and strengths of the present invention will be made clear by the description below. Further, the advantages of the present invention will be evident from the following explanation in reference to the drawings.

### BRIEF DESCRIPTION OF DRAWINGS

FIG. 1(a) is a plan view showing a schematic configuration of a pixel of a TFT array substrate in a liquid crystal display device according to one Embodiment of the present invention.

FIG. 1(b) is a cross-sectional view, taken along the line A-A of FIG. 1(a).

FIG. 2 is a perspective view schematically showing a pattern forming equipment using an inkjet method, and is used for manufacturing of a liquid crystal display device according to one Embodiment of the present invention.

FIG. 3 is a flow chart showing manufacturing steps of the TFT array substrate shown in FIG. 1.

FIG. 4(a) is a plan view of a TFT array substrate for explaining the gate line pre-processing step shown in FIG. 3.

FIG. 4(b) is a plan view of a TFT array substrate for explaining the gate line applying/forming step shown in FIG. 3.

FIG. 4(c) is a cross-sectional view, taken along the line B-B of FIG. 4(b).

FIGS. 5(a) through 5(c) are cross-sectional views corresponding to a portion taken along the line B-B of FIG. 4(b), and FIG. 5(a) shows the gate insulation layer/semiconductor layer depositing step, FIG. 5(b) shows how a thermosetting resin is formed on the semiconductor layer in the semiconductor layer forming step shown in FIG. 3, FIG. 5(c) shows an etching process of the a-Si forming layer and the n+ forming layer in the same step, and FIG. 5 (d) is a cross-sectional view, taken along the line C-C of FIG. 5(e), showing a resist removal process in the same step, and FIG. 5(e) is a plan view of a TFT array substrate after the semiconductor layer forming step.

FIG. 6(a) is a plan view of a TFT array substrate for explaining the source/drain lines pre-processing step shown in FIG. 3.

FIG. 6(b) is a plan view of a TFT array substrate for explaining the source/drain lines applying/forming step.

FIG. 6(c) is a cross-sectional view, taken along the line D-D of FIG. 6(b).

FIG. 7 is a plan view showing a TFT section in the TFT array substrate shown in FIG. 1(a).

FIGS. 8(a) and 8(b) are cross-sectional views corresponding to a portion taken along the line D-D of FIG. 6(b), and FIG. 8(a) shows removal process of wiring guide in the channel section processing step shown in FIG. 3, and FIG. 8(b) shows oxidation treatment of the n+ layer in the same step.

FIG. 9(a) is a plan view of a TFT array substrate for explaining the passivation film forming step and the passivation film processing step, which are shown in FIG. 3.

FIG. 9(b) is a cross-sectional view, taken along the line E-E of FIG. 9(a).

FIG. 10(a) is a plan view of a TFT array substrate for explaining the pixel electrode forming step shown in FIG. 3.

FIG. 10(b) is a cross-sectional view, taken along the line F-F of FIG. 10(a).

FIGS. 11(a) and 11(b) are explanatory views showing mechanism of occurrence of a leak current in the TFT section shown in FIG. 1(a), and FIG. 11(a) is a plan view showing the TFT section with the gate electrode penetrating through the semiconductor pattern, and FIG. 11(b) is a cross-sectional view, taken along the line G-G of FIG. 11(a).

FIG. 12(a) is a plan view of the TFT section in which the gate electrode does not penetrate through the semiconductor pattern, in contrast to the configuration of FIG. 11(a), for showing the mechanism of occurrence of a leak current.

FIG. 12(b) is a cross-sectional view, taken along the line H-H of FIG. 12(a).

FIG. 13 is a plan view showing the TFT section shown in FIG. 1(a) when the a-Si layer is not balanced with respect to the gate electrode.

FIG. 14(a) is a vertical cross-sectional view for explaining a manufacturing method of the TFT array substrate having an upper light blocking film in addition to a lower light blocking film, and shows a state of the TFT array substrate when a partial oxidation treatment of the channel section is completed.

FIG. 14(b) is a vertical cross-sectional view of the TFT array substrate showing the step for forming an upper light blocking film.

FIG. 14(c) is a cross-sectional view, taken along the lines M-M of FIG. 14(d).

FIG. 14(d) is a plan view of the TFT array substrate showing a state where forming of a pixel electrode is completed.

FIG. 15(a) is a plan view showing a schematic configuration of a pixel of a TFT array substrate in a liquid crystal display device according to another Embodiment of the present invention.

FIG. 15(b) is a cross-sectional view, taken along the line I-I of FIG. 15(a).

FIG. 16 is a flow chart showing manufacturing steps of the TFT array substrate shown in FIGS. 15(a) and 15(b).

FIG. 17 is a plan view of a TFT array substrate for explaining the source and drain/pixel electrodes pre-processing step shown in FIG. 16.

FIG. 18(a) is a plan view of a TFT array substrate for explaining the source line applying/forming step shown in FIG. 16.

FIG. 18(b) is a cross-sectional view, taken along the line J-J of FIG. 18(a).

FIG. 19(a) is a plan view for explaining the drain/pixel electrodes applying/forming step shown in FIG. 16.

FIG. 19(b) is a cross-sectional view, taken along the line K-K of FIG. 19(a).

FIGS. 20(a) and 20(b) are cross-sectional views corresponding to a portion taken along the line K-K of FIG. 19(a), and FIG. 20(a) shows removal process of a wiring guide in the channel section processing step shown in FIG. 16, and FIG. 20(b) shows an oxidation treatment of the n+ layer in the same step.

FIG. 21 is a cross-sectional view corresponding to a portion taken along the line K-K of FIG. 19(a) for explaining the passivation film forming step shown in FIG. 16.

FIG. 22(a) is a cross-sectional view showing a TFT array substrate according to still another Embodiment of the present invention, and shows a state of the TFT array substrate before provided with a semiconductor layer.

FIG. 22(b) is a cross-sectional view, taken along the line L-L of FIG. 22(c), showing the TFT array substrate provided with a semiconductor layer.

FIG. 22(c) is a plan view showing the TFT array substrate provided with a semiconductor layer.

FIG. 23 is a plan view showing a schematic configuration of a pixel of a TFT array substrate in a liquid crystal display device according to yet another Embodiment of the present invention.

FIG. 24 is an explanatory view showing a droplet having substantially a round shape, as an example of the shape of droplet dropped from the pattern forming equipment shown in FIG. 2.

FIG. 25 (a) is an explanatory view showing a droplet having a substantially circular shape by being deformed from a circle, as another example of the shape of the droplet shown in FIG. 24.

FIG. 25(b) is an explanatory view showing a shape having a concave portion.

FIG. 25(c) is an explanatory view showing a shape partly including a convex portion.

FIG. 26(a) shows a case where an irregular oval shape is formed by two droplets.

FIG. 26(b) is an explanatory view showing a shape formed by three droplets.

FIG. 27 (a) is an explanatory view showing a state, which is not desired in the present invention, where plural infinitesimal droplets are dropped.

FIG. 27(b) is an explanatory view showing a shape formed by the state of FIG. 27(a).

FIG. 28 is a flow chart showing manufacturing steps of a TFT array substrate for a conventional liquid crystal display device.

FIG. 29 is a graph showing a TFT characteristic of a TFT array substrate according to the present invention.

FIG. 30 is a magnified view of a TFT section of a TFT array substrate, with the gate electrode having an open end not penetrating through the semiconductor layer.

FIG. 31 is a magnified view of a TFT section of a TFT array substrate, with the gate electrode having an open end penetrating through the semiconductor layer.

FIG. 32 is a magnified view of a TFT section of a TFT array substrate, with the gate electrode having an open end penetrating through the semiconductor layer.

FIG. 33 is a plan view showing a schematic configuration of a pixel of a TFT array substrate in a liquid crystal display device according a further Embodiment of the present invention.

FIG. 34 is a plan view showing a schematic configuration of a pixel of a TFT array substrate in a liquid crystal display device according a still further Embodiment of the present invention.

FIG. 35 is a magnified view of the main part of a pixel in the TFT array substrate shown in FIG. 33.

FIG. 36 is a magnified view of the main part of a pixel in the TFT array substrate shown in FIG. 34.

FIG. 37 is an explanatory view for regulating the relation between an open end of the gate electrode in the TFT section and the border line area of the semiconductor layer.

FIG. 38 is another explanatory view for regulating the relation between the open end of the gate electrode in the TFT section and the border line area of the semiconductor layer.

FIG. 39(a) is a plan view showing a schematic configuration of a pixel of a TFT array substrate in a liquid crystal display device according a yet further Embodiment of the present invention.

FIG. 39(b) is a cross-sectional view, taken along the line M-M of FIG. 39(a).

FIG. 40 is a flow chart showing manufacturing steps of the TFT array substrate shown in FIGS. 39(a) and 39(b).

FIG. 41(a) is a cross-sectional view corresponding to a portion taken along the line N-N of FIG. 41(d), showing a condition ready for the gate insulation layer/semiconductor layer depositing step shown in FIG. 40.

FIG. 41(b) is a cross-sectional view corresponding to a portion taken along the line N-N of FIG. 41(d), showing a condition during the semiconductor layer forming step shown in FIG. 40.

FIG. 41(c) is a cross-sectional view, taken along the line N-N of FIG. 41(d), showing completion of the gate insulation layer/semiconductor layer depositing step shown in FIG. 40.

FIG. 41 (d) is a plan view of a glass substrate after the semiconductor layer forming step.

FIG. 42(a) is a plan view of a TFT array substrate for explaining the source/drain lines pre-processing step shown in FIG. 40.

FIG. 42(b) is a plan view of a TFT array substrate for explaining the source and drain lines applying/forming step.

FIG. 42(c) is a cross-sectional view, taken along the line O-O of FIG. 42(b).

FIGS. 43(a) through 43(c) are cross-sectional views corresponding to a portion taken along the line O-O of FIG. 42(b), and FIG. 43(a) shows removal process of wiring guide in the channel section processing step shown in FIG. 40, FIG. 43(b) shows a partial etching process of a conductor forming layer in the same step, and FIG. 43(c) shows partial oxidation treatment of the n+ layer in the same step.

### BEST MODE FOR CARRYING OUT THE INVENTION

### First Embodiment

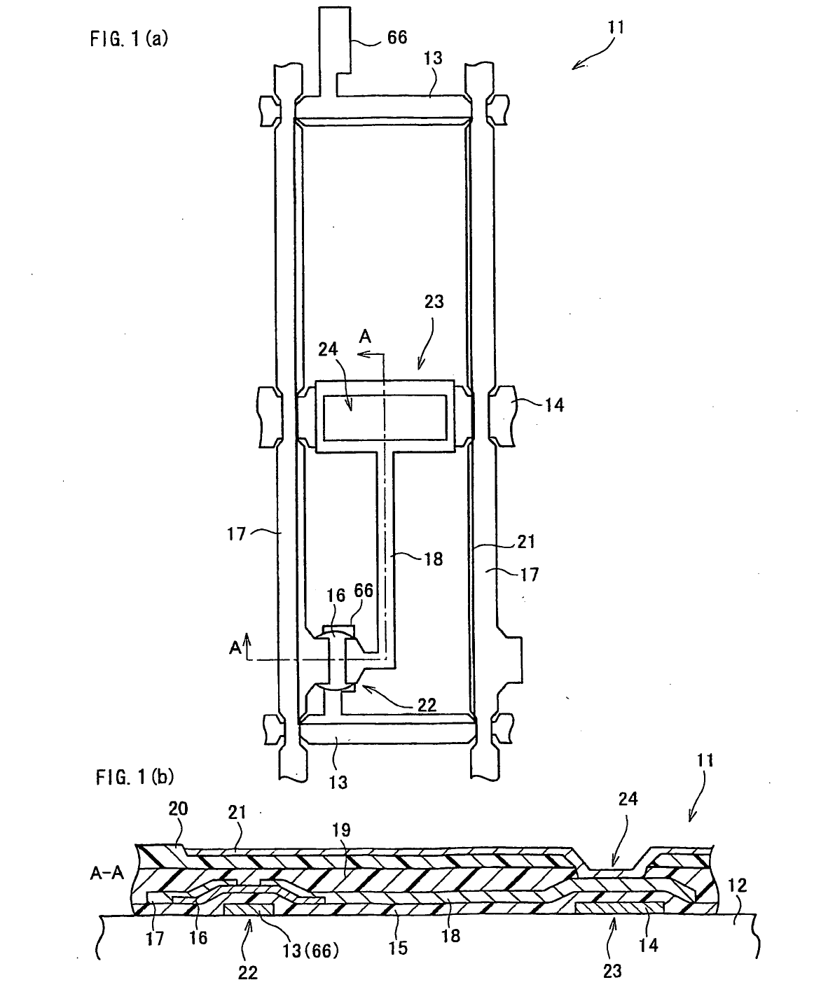

One Embodiment of the present invention is described below with reference to FIGS. 1 through 13.

A liquid crystal display device according to the present Embodiment includes a pixel shown in FIG. 1(a). Note that, FIG. 1(a) is a plan view showing a schematic configuration of a pixel of a TFT array substrate in the liquid crystal display device. Further, FIG. 1(b) is a cross-sectional view, taken along the line A-A of FIG. 1(a).

As shown in FIGS. 1(a) and 1(b), a TFT array substrate 11 is made of a glass substrate 12 on which a gate electrode 13 and a source electrode 17 are aligned in a matrix manner. A storage capacitor electrode 14 is provided between two adjacent gate electrodes 13.

As shown in FIG. 1(b), in the TFT array substrate 11, the gate electrode 13 and the storage capacitor electrode 14 are provided on the glass substrate 12 in an area between a TFT section 22 and an storage capacitor section 23; and a gate insulation layer 15 is further provided thereon.

Further, a semiconductor layer 16 including an a-Si layer is formed on the gate electrode 13 via the gate insulation layer 15, and the source electrode 17 and a drain electrode 18 are further formed thereon. One end of the drain electrode 18 extends to an area on the storage capacitor electrode 14 by having the gate insulation layer 15 underneath, and a contact hole 24 is formed on this area. A passivation film 19 is formed on the source electrode 17 and the drain electrode 18, and a photosensitive acrylic resin layer 20 and a pixel electrode 21 are further formed thereon in this order.

In the present Embodiment, manufacturing of the TFT array substrate 11 is performed with a pattern forming equipment. This pattern forming equipment discharges or drops material of the layer with an inkjet method, for example.

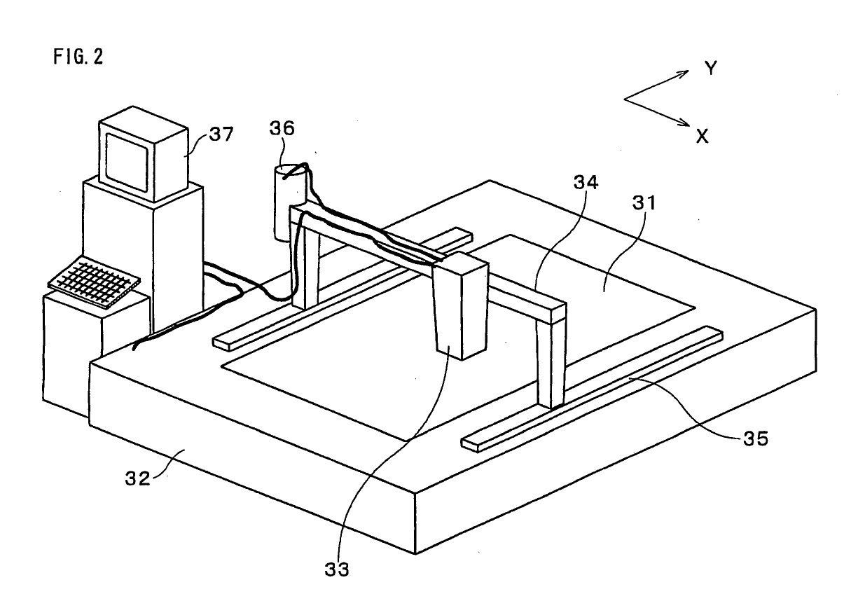

As shown in FIG. 2, the pattern forming equipment includes a supporting stage 32 on which a substrate 31 (corresponding to the glass substrate 12) is placed. The pattern forming equipment includes an inkjet head 33 as droplet discharging means for discharging, for example, fluid ink (droplet) containing a wiring material, with respect to the surface of the substrate 31 placed on the supporting stage 32, and an X-direction driving section 34 for moving the inkjet head 33 in the X-direction, as denoted in the figure, and a Y-direction driving section 35 for moving the inkjet head 33 in the Y-direction of the figure.

Further, the pattern forming equipment includes an ink supplying system 36 for supplying ink to the inkjet head 33, and also includes a control unit 37. The control unit 37 performs various controls including driving control for the X-direction driving section 34 and the Y-direction driving section 35, and discharge control for the inkjet head 33. The control unit 37 supplies information for indicating the position where the ink is applied, with respect to the X and Y-direction driving sections 34 and 35, and supplies discharge information to a head driver (not shown) of the inkjet head 33. With this arrangement, the inkjet head 33 is shifted by the X-direction driving section 34 and Y-direction driving section 35 so that the substrate 31 is provided with desired amount of droplet in a target position on its surface.

The inkjet head 33 may be of a piezo-type using a piezoactuator, a bubble-type including a heater in the head, or the like. The discharge amount of the inkjet head 33 may be controlled according to an application voltage. Further, the droplet discharging means may be any means capable of supplying a droplet; therefore, the inkjet head 33 may instead be a device having only a droplet dropping function, for example.

Next, the following will explain a manufacturing method of the TFT array substrate 11 for a liquid crystal display device according to the present invention.

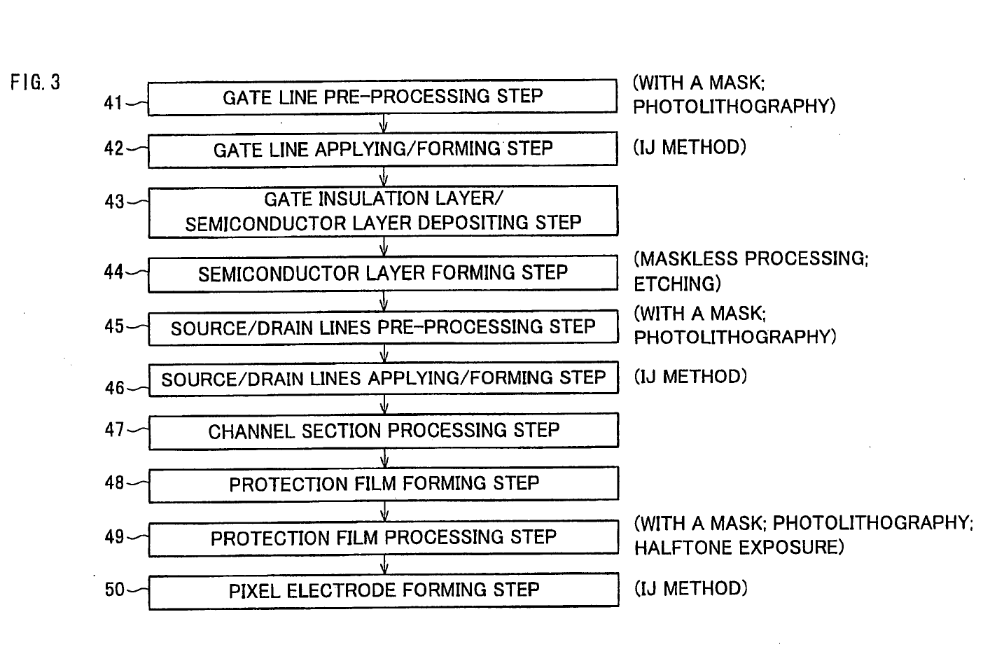

In the present Embodiment, the TFT array substrate 11 is manufactured through, as shown in FIG. 3, a gate line pre-processing step 41, a gate line applying/forming step 42, a gate insulation layer/semiconductor layer depositing step 43, a semiconductor layer forming step 44, a source/drain lines pre-processing step 45, a source/drain lines applying/forming step 46, a channel section processing step 47, a passivation film forming step 48, a passivation film processing step 49, and a pixel electrode forming step 50.

[Gate Line Pre-Processing Step 41]

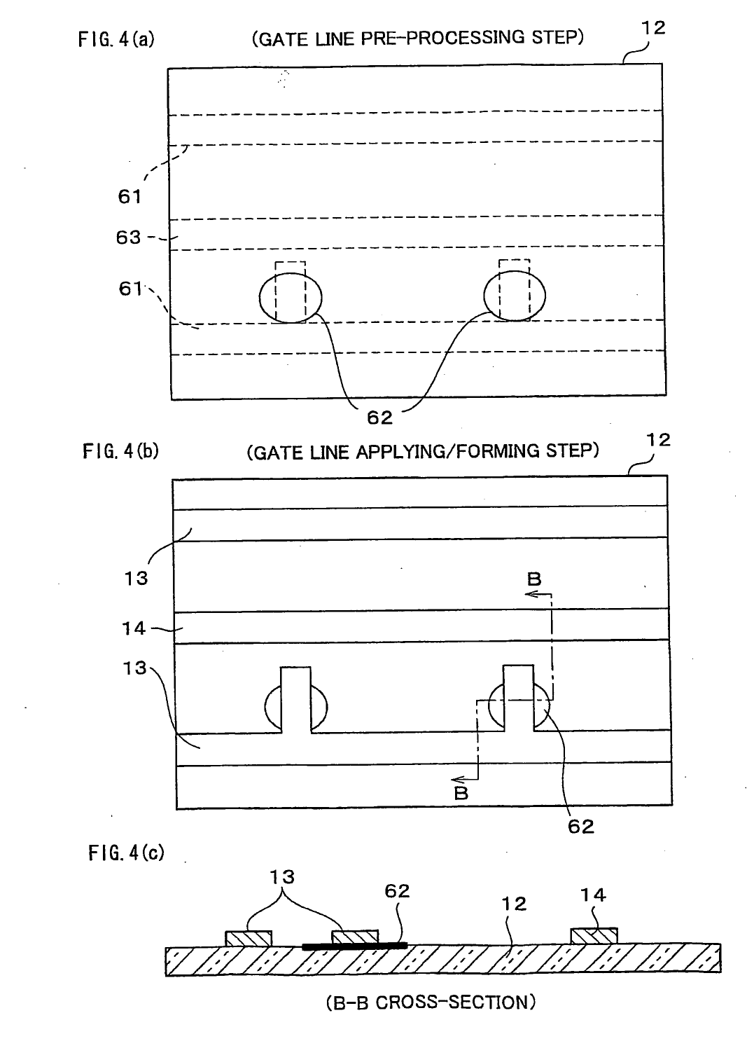

The gate line pre-processing step 41 is performed as a pre-processing of the gate line applying/forming step 42. The gate line applying/forming step 42 as the following step is performed for forming a gate electrode 13, an storage capacitor electrode 14 etc. by dropping liquid wiring material with a pattern forming equipment. Therefore, this step carries out preparation for appropriate liquid wiring material application, i.e., appropriate discharging (dropping) of the liquid wiring material from a pattern forming equipment with respect to a gate line forming area 61 and an storage capacitor electrode forming area 63 shown in FIG. 4(a). Note that, FIG. 4(a) is a plan view of a glass substrate 12 included in the TFT array substrate 11.

This step falls roughly into two processes. In hydrophilic/hydrophobic processing (lyophilic/lyophobic processing) as the first process, the substrate is provided with either lyophilic characteristic or lyophobic characteristic with respect to the liquid wiring material, so as to pattern a hydrophilic (lyophilic) area as an area for forming the gate line 61 etc., and a hydrophobic (lyophobic) area as an area for not forming such electrodes. In a guide forming process as the second step, the substrate is provided with guides along the gate line forming area 61 etc., for controlling flow of the liquid.

The first step, i.e., the hydrophilic/hydrophobic processing is typically performed by a photocatalyst containing titanium oxide. The second step, i.e., the guide forming is performed by photolithography using a resist material. Occasionally, the guide or the surface of the substrate may be exposed to CF₄/O₂ plasma so as to obtain hydrophilic/hydrophobic characteristics. The resist is removed after the wiring is formed.

In the present Embodiment, the hydrophilic/hydrophobic processing was performed by a photocatalyst using titanium oxide, as described below.

The glass substrate 12 of the TFT array substrate 11 was coated with a ZONYL FSN (Product Name: provided by Dupont-TORAY Co. ltd), which is a fluorochemical nonionic surfactant which had been mixed with an isopropyl alcohol. Further, a mask of the pattern for the gate electrode 13 etc. was provided with a photocatalyst layer by subjecting the mask spin-coating with a mixture containing titanium dioxide particle dispersing element and an ethanol, and then by baking the mask at 150°. Next, the glass substrate 12 was exposed to ultraviolet light with the mask. This exposure was performed for two minutes using irradiation of ultraviolet light of 365 nm on condition of 70 mW/cm².

Here, when it is predicted that the semiconductor layer 16 on the glass substrate 12 is exposed to intensive light, a light blocking film 62 may be formed in advance, as shown in FIG. 4(a), so as to prevent the semiconductor layer 16 from the light. The light blocking film 62 is formed by dropping the material of film by a pattern forming equipment with respect to a position where an a-Si layer is formed, and then by baking the dropped material. This material of the film may be a photosensitive resin or a thermosetting resin, which is mixed with a black colored material such as a carbon black or TiN.

Note that, for ease of explanation, the electrode for forming the TFT, which is branched out of the gate electrode, is omitted in the upper gate electrode of FIG. 4 and later drawings.

[Gate Line Applying/Forming Step 42]

FIGS. 4(b) and 4(c) show the gate line applying/forming step 42. FIG. 4(b) is a plan view of the glass substrate 12 provided with the gate electrode 13, and FIG. 4(c) is a cross-sectional view, taken along the line B-B of FIG. 4(b).

In this step, as shown in FIGS. 4(b) and 4(c), a material of wiring is applied onto the gate line forming area 61 and the storage capacitor electrode forming area 63 on the glass substrate 12 with a pattern forming equipment. In this Embodiment, an organic solvent in which Ag particles coated with an organic film are dispersed was used as the wiring material. The wiring width was adjusted to approximately 50 μm, and discharge amount of the wiring material from the inkjet head 33 was adjusted to 80 pl.

In the area processed to have hydrophilic/hydrophobic characteristics, the wiring material discharged from the inkjet head 33 spreads along the gate line forming area 61, and therefore, the space between each discharging of the wiring material was adjusted to approximately 500 μm. After the discharging, the material was baked for an hour with a baking temperature of 350° C. so as to complete the wiring of the gate electrode 13.

Note that, the baking temperature of 350° C. in this example was determined in consideration of the coming semiconductor layer forming step 44 in which processing heat of about 300° C. will be added. Thus, the baking temperature is not limited to this temperature. For example, in case of forming an organic semiconductor, the baking temperature may be decreased to a range from 200 to 250° C., if the annealing temperature is set to 100 to 200° C.

Further, in addition to Ag, the wiring material may also be Ag—Pd, Ag—Au, Ag—Cu, Cu, Cu—Ni etc. These materials may be individually adopted, or in a form of particles of an alloy material, or as a paste dissolved in an organic solvent. Further, each dissociation temperature of the coating layer on the surface of the particles and the organic material dissolved in the solvent may be controlled according to the required baking temperature so that the wiring material has a desired resistance value and surface condition. Note that, the dissociation temperature designates a temperature for causing vaporization of the coating layer on the surface and the solvent.

[Gate Insulation Layer/Semiconductor Layer Depositing Step 43]

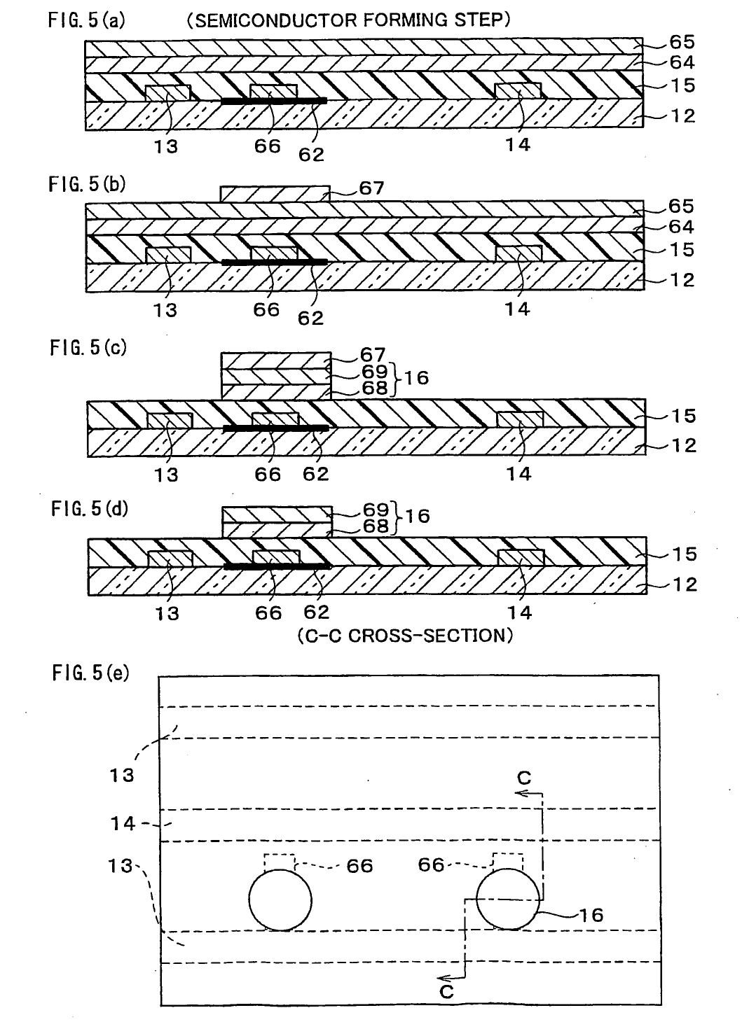

FIG. 5(a) shows the gate insulation layer/semiconductor layer depositing step 43. In this step, the gate insulation layer 15, the a-Si forming layer 64, and the n+ forming layer 65 are continuously formed in this order on the glass substrate 12, which has been through the gate line applying/forming step 42. In this Embodiment, the a-Si forming layer 64 was made by a CVD method. The thicknesses of the gate insulation layer 15, the a-Si forming layer 64, and the n+ forming layer 65 are set to 0.3 μm, 0.15 μm, and 0.04 μm, respectively, and each layer was formed continuously without taking the substrate from the vacuum equipment. The deposition temperature was 300° C.

[Semiconductor Layer Forming Step 44]

FIGS. 5(b) through 5(e) show the semiconductor layer forming step 44. FIG. 5(e) is a plan view showing the glass substrate 12 after the semiconductor layer forming step 44, FIG. 5 (d) is a cross-sectional view, taken along the line C-C of FIG. 5(e), and FIGS. 5(b) and 5(c) are cross-sectional views showing respective processes in the portion of FIG. 5(d).

In this step, as shown in FIG. 5(b), a thermosetting resin as the resist material was dropped from a pattern forming equipment onto the n+ forming layer 65 in a portion right above a TFT section gate electrode (branch electrode) 66, which is branched out from the main line of the gate electrode 13. The resin thus applied by dropping was then formed to be a resist layer 67, which is used as a processing pattern. The discharging amount of the resist material was a 10 pl droplet. As a result, a circular pattern with a diameter=30 μm was formed on a predetermined position above the TFT section gate electrode 66. Then the pattern was baked with the baking temperature of 150° C. As to the thermosetting resin for forming the resist layer 67, the present Embodiment used a resist of TEF series (provided by Tokyo Ohka Kogyo co. ltd.) whose viscosity had been adjusted in advance to be used for an inkjet method.

Note that, in addition to the thermosetting resin, an UV resin or a photoresist may also be used as the material of the resist layer 67. Further, though it is not a required condition, a transparent resist layer 67 makes positioning upon forming easier. Further, it is preferable that the resist layer 67 is resistant to the heat upon etching, resistant to dry etching gas, and has good selectivity to etching materials.

Next, as shown in FIG. 5(c), the n+ forming layer 65 and the a-Si forming layer 64 were subjected to dry etching using a gas (such as SF₆+HCl) so as to form an n+ layer 69 and an a-Si layer 68. Thereafter, the glass substrate 12 was washed by an organic solvent, and the resist layer 67 was removed, as shown in FIG. 5(d).

As described, in the semiconductor layer forming step 44, the resin pattern (the pattern of the resist layer 67) discharged from a pattern forming equipment determines the shape of the semiconductor layer 16 which is made up of the n+ layer 69 and the a-Si layer 68. Namely, the semiconductor layer 16 is formed as a circular or substantially a circular pattern made up of a curved line, according to the shape of the material of the resist layer 67 dropped on the glass substrate 12 from the inkjet head 33.

Though the resist layer 67 of this embodiment is formed by s single droplet with a pattern forming equipment, the resist layer 67 may also be formed by plural droplets. However, it should be noted that, when the resist layer 67 is formed by a plurality of extremely small droplets, forming of a semiconductor layer 16 takes a long period of time, and also the life of the inkjet head 33 is shortened as more dot number is required.

When forming a desirable size of layer (film) by dropping droplets with the inkjet head 33, it is important to drop an appropriate amount of droplet with a minimum number of shots. In this way, it is possible to carry out maximum number of processings within the life period of the inkjet head 33, thus minimizing device cost.

Further, as another noticeable characteristic of the semiconductor layer forming step 44, no particular processing is necessary for the surface to be supplied with droplets discharged from the inkjet head 33. More specifically, if the surface to be supplied with droplets is significantly hydrophilic, the discharged droplet will spread in an infinite form unless the surface is patterned. In such a condition, the film forming cannot be performed. However, since it contains a large number of Si dangling bonds, the a-Si forming layer 64 is basically hydrophobic. Therefore, the droplet is applied on the a-Si forming layer 64 with a certain large degree of contact angle, and results in a substantially circular shape. Accordingly, no particular processing is required for the substrate (a-Si forming layer 64).

Further, a substrate which has been subjected to baking or processing in a gas (dry etching) etc. often has substances in a form of a short molecular on its surface. Therefore, the discharged droplet is likely to forms a certain large degree of contact angle, even when using other semiconductor than a-Si, such as an organic semiconductor.

Conventionally, patterning of a semiconductor layer requires a mask and photolithography processing. However, in the semiconductor layer forming step 44, the mask pattern is directly drawn with a droplet dropped from the inkjet head 33, thus not requiring a mask and photolithography processing. Therefore, by adopting this step, manufacturing cost can be greatly reduced.

[Source/Drain Lines Pre-Processing Step 45]

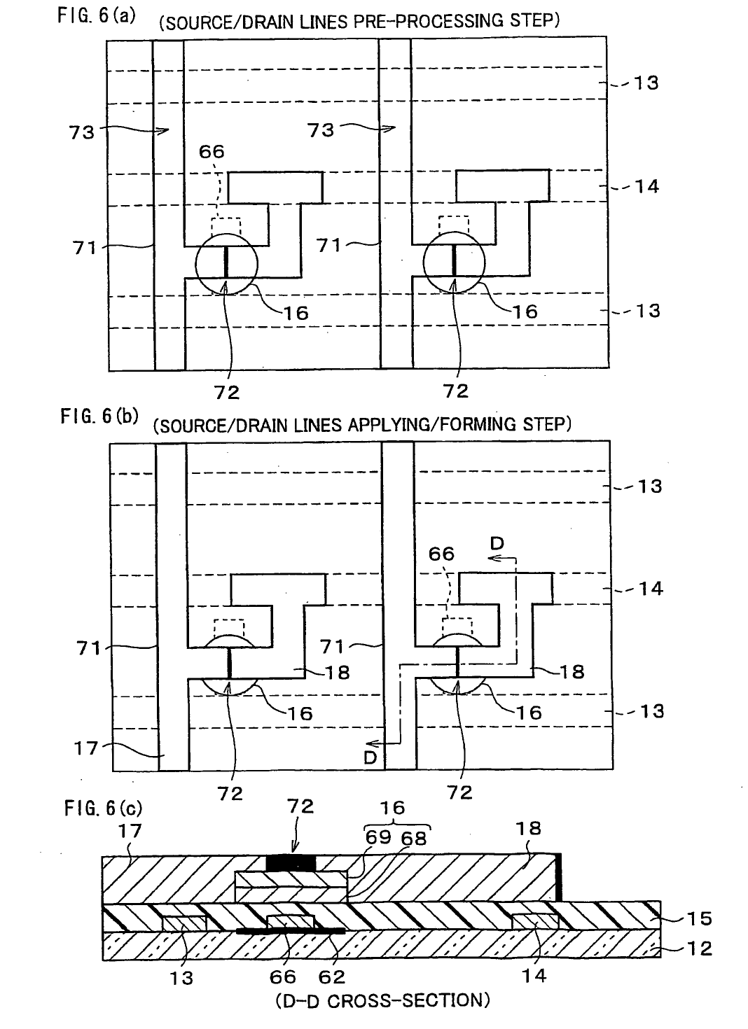

FIG. 6(a) shows the source/drain lines pre-processing step 45. FIG. 6(a) is a plan view showing the glass substrate 12 which has been through the semiconductor layer forming step 44, and provided with a wiring guide 71 for forming the source and drain electrodes 17 and 18.

In this step, the wiring guide 71 is formed on an area (source/drain forming area 73) on which the source electrode 17 and the drain electrode 18 and the drain electrode 18 will be formed. In this Embodiment, the wiring guide 71 was formed by a photoresist material. More specifically, the glass substrate 12 after the semiconductor layer forming step 44 was coated with a photoresist, subjected to pre-baking, exposed using a photo mask, developed, and then subjected to post-baking. The wiring guide 71 thus created had a width =10 μm, and the width of the groove (the width of the wiring forming area) created with the wiring guide 71 was approximately 15 μm. Note that, the interval between the source and drain electrodes, i.e., the channel section 72 was set to 4 μm.

Note that, here, the glass substrate 12 may be arranged such that the SiNx surface (the upper surface of the gate insulation layer 15) is processed to have hydrophilicity by an oxygen plasma, and the wiring guide 71 is processed to have water-repellence by exposing to CF₄ plasma, so that the wiring material from a pattern forming equipment can be smoothly applied to the base surface.

Further, instead of forming the wiring guide 71, the glass substrate 12 may be subjected to the hydrophilic/hydrophobic processing using a photocatalyst according to the pattern of wiring electrode, as with the foregoing gate electrode forming step.

[Source/Drain Lines Applying/Forming Step 46]

FIGS. 6(b) and 6(c) show the source/drain lines applying/forming step 46. FIG. 6(b) is a plan view showing the source and drain electrodes 17 and 18 which are formed along the wiring guide 71, and FIG. 6(c) is a cross-sectional view, taken along the line D-D of FIG. 6(b).

As shown in FIGS. 6(b) and 6(c), in this source/drain lines applying/forming step 46, the source electrode 17 and the drain electrode 18 were formed by coating the source/drain forming area 73, which is formed by the wiring guide 71, with a wiring material by using a pattern forming equipment. Here, the discharging amount of the wiring material from the inkjet head 33 was set to 2 pl. Further, Ag particles are used as the wiring material, and the thicknesses of the electrodes were adjusted to 0.3 μm. Further, baking temperature was 200° C., and after the baking, the wiring guide 71 was removed by an organic solvent.

Note that, in this step, the same wiring material may be used as the one used for the gate electrode 13; however, the baking temperature is required to be at or lower than 300° C., since the a-Si is formed at around 300° C.

Then, the basic structure of a TFT is almost completed by thus being through the Gate line pre-processing step 41 through the source/drain lines applying/forming step 46.

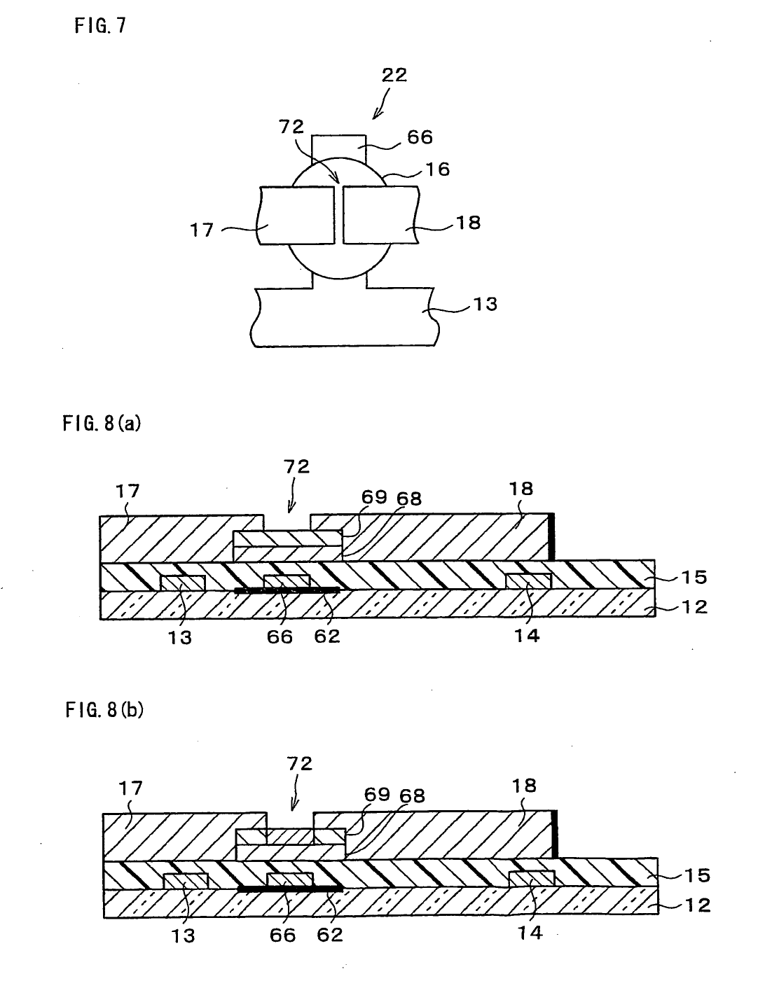

Here, in the TFT section 22, it is important that the TFT gate electrode 66 of the gate electrode 13 penetrates through the semiconductor pattern (a semiconductor layer 16) having substantially a circular shape, as shown in FIG. 7. In an arrangement in which the TFT section gate electrode 66 is formed within the semiconductor pattern, a leak current will flow between the source and drain electrodes through a semiconductor area on which the electrical field from the TFT section gate electrode 66 does not sufficiently affect, even if the gate is OFF. This phenomenon will be described later in detail. Note that, in the practical use of the TFT, the foregoing structure generates desirable photoconductor even though the semiconductor pattern is extending out of the TFT section gate electrode 66, the source electrode 17, and the drain electrode 18.

[Channel Section Processing Step 47]

This step is carried out for processing the channel section 72, as shown in FIGS. 8(a) and 8(b). FIGS. 8(a) and 8(b) are cross-sectional views corresponding to a portion taken along the line D-D of FIG. 6(b). Firstly, as shown in FIG. 8(a), the wiring guide 71 of the channel section 72 was removed by an organic solvent or by ashing. Next, as shown in FIG. 8(b), the n+ layer 69 was subjected to oxidation treatment by ashing or by using a laser so as to be a nonconductor.

[Passivation Film Forming Step 48, Passivation Film Processing Step 49]

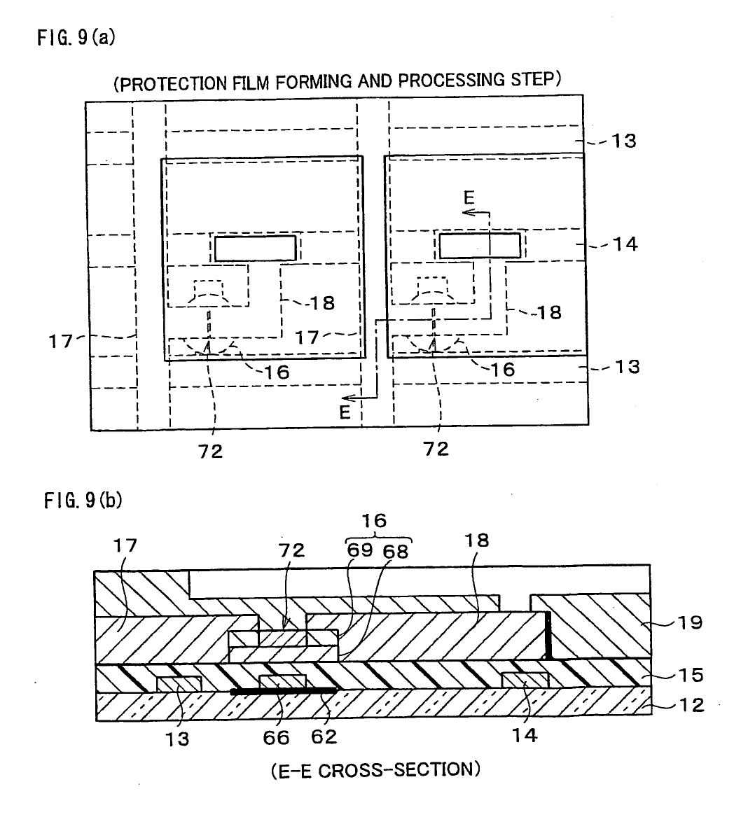

FIGS. 9(a) and 9(b) show a state where the passivation film processing step 49 is completed.

In this step, as shown in FIGS. 9(a) and 9(b), a SiO₂ film as a passivation film 19 was formed by a CVD on a glass substrate 12 which had been provided with the source and drain electrodes.

Next, the SiO₂ film was coated with an acrylic resist material so as to create a photosensitive acrylic resin layer 20, and then a pixel electrode forming pattern (see FIG. 9(b)) and a terminal processing pattern were formed in this resist layer.

The pixel electrode pattern and the terminal processing pattern were formed by a mask for creating a portion where the resist layer is completely removed, and a portion where the resist layer is removed by a half of the thickness, after the development. The latter portion is an area for halftone exposure, whose transmittance of mask is 50%. More specifically, the resist layer is completely removed in the portion for forming a terminal by subjecting the passivation film 19 and the gate insulation layer 15 to etching, and meanwhile, the resist layer is removed to be half in thickness in the portion for forming a pixel electrode 21 so as to create a guide with the photosensitive acrylic resin layer 20 in the periphery of the pixel electrode pattern. Next, by using the resist layer as a mask, the passivation film 19 and the gate insulation layer 15 in the terminal section were removed, and the passivation film 19 in the portion for forming a pixel electrode 21 were partly removed by etching.

[Pixel Electrode Forming Step 50]

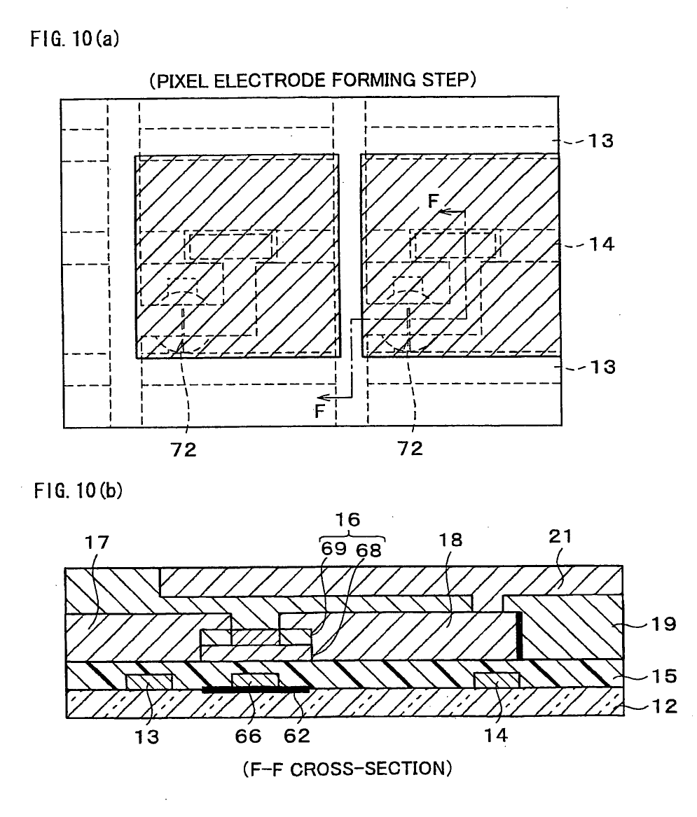

As shown in FIGS. 10(a) and 10(b), the pixel electrode forming pattern on the photosensitive acrylic resin layer 20 was coated with an ITO particle material for creating a pixel electrode by using a pattern forming equipment, and then was baked with a temperature of 200° C. so as to form a pixel electrode 21. Here, a TFT array substrate 11 is completed.

Conventional photolithography requires a mask in both the passivation film processing and an ITO processing, respectively. On the other hand, by carrying out halftone exposure with a photosensitive acrylic resin, those processings can be carried out with a single mask, thus reducing the manufacturing cost.

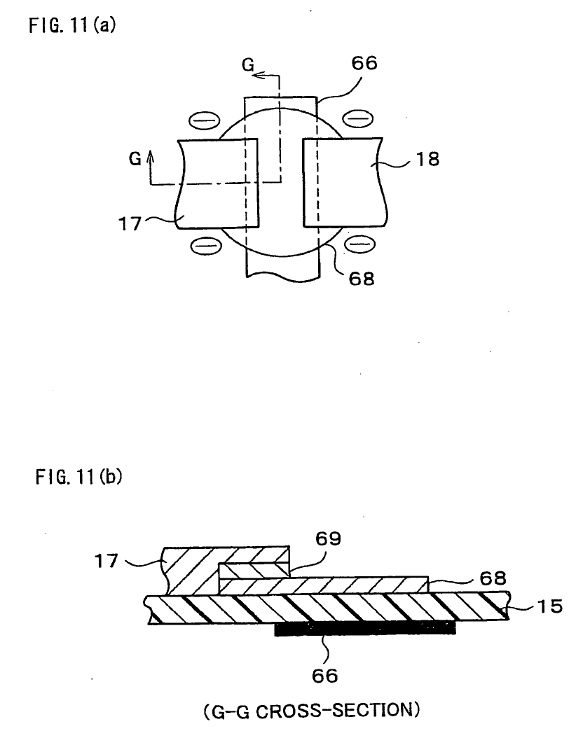

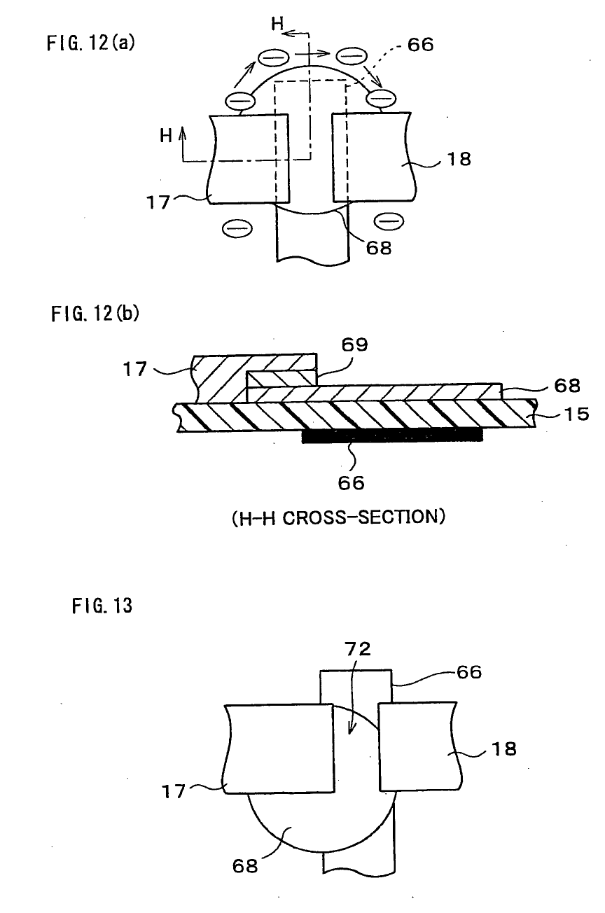

Here, with reference to FIGS. 11(a) and 11(b), and FIGS. 12(a) and 12(b), the following will explain the generation mechanism of a leak current, which was mentioned in the source/drain lines applying/forming step 46.

FIG. 11(a) is a plan view showing the TFT section with the TFT section gate electrode 66 penetrating through the semiconductor pattern (semiconductor layer 16), and FIG. 11(b) is a cross-sectional view, taken along the line G-G of FIG. 11(a). FIG. 12(a) is a plan view showing the TFT section with the TFT section gate electrode 66 not penetrating through the semiconductor pattern and is provided within the semiconductor pattern area. FIG. 12(b) is a cross-sectional view, taken along the line H-H of FIG. 12(a). Further, FIGS. 11(a) and 12(a) show a state where a negative potential is applied to the gate electrode 13. As shown in FIGS. 11(b) and 12(b), the TFT section gate electrode 66 and the a-Si layer 68 are opposed to each other having the gate insulation layer 15 therebetween. Here, the n+ layer. 69 is a layer to inject carriers into the a-Si layer 68, and provided with an excessive number of electrons through doping of such as a phosphorous (P).

For the respective TFTs shown in FIGS. 11(a) and 11(b) (the TFT section gate electrode 66 penetrating through the semiconductor pattern), and FIGS. 12(a) and 12(b) (the TFT section gate electrode 66 not penetrating through the semiconductor pattern), a voltage of −4V was applied to the gate electrode, and a leak current between the source and drain electrodes were measured. The measurement came out as: the leak current in the TFT section gate electrode 66 penetrating through the semiconductor pattern was approximately 1 pA. Meanwhile, the leak current in the TFT section gate electrode 66 not penetrating through the semiconductor pattern increased to 30 to 50 pA.

The measurement was carried out under dark circumstances, and in the presence of irradiation of a backlight, the leak current in the TFT section gate electrode 66 penetrating through the semiconductor pattern increased to 20 pA. Meanwhile, the leak current in the TFT section gate electrode 66 not penetrating through the semiconductor pattern greatly increased to approximately 2000 to 3000 pA. These results show that the TFT characteristic deteriorates in the arrangement with the TFT section gate electrode not penetrating through the semiconductor pattern. Further, reasons for those results may be explained as follows.

Firstly, the following will explain the case where a negative potential is applied to the gate electrode 13. When a gate electrode is supplied with a negative potential, due to repulsive force between a negative charge and a negative charge, carriers (electrons) are away from the TFT section gate electrode 66, as shown in FIG. 11(a). Accordingly, the electrons mostly exist in the vicinity of the source and drain electrodes, and few electrons exist in the a-Si layer 68 of the channel section. Thus, the TFT is OFF in this state. Even if the electrons goes from the gate toward the drain, they have to pass the TFT section gate electrode 66. In this case, since the TFT section gate electrode 66 is supplied with a negative potential, the electrons cannot pass through the gate electrode due to repulsive force between a negative charge and a negative charge. Accordingly, a leak current is small in this arrangement.

Meanwhile, in the arrangement shown in FIG. 12(a), in which the a-Si layer 68 extends beyond the front end portion of the TFT section gate electrode 66, the electrons can move along the periphery of the a-Si layer 68 without passing through the TFT section gate electrode 66, even when the gate electrode has negative potential. This allows the leak current to easily flow. Further, in the presence of irradiation of backlight, carriers are generated due to excitation by the backlight. For the same reason above, these generated carriers can also flow along the periphery of the a-Si layer 68.

Therefore, upon backlight irradiation, the increase amount of the leak current greatly varies between the arrangement of FIG. 11(a) with the TFT section gate electrode penetrating through the semiconductor pattern, and in the arrangement of FIG. 12(a) with the TFT section gate electrode not penetrating through the semiconductor pattern.

As can been seen with the explanation above, it is necessary in the TFT section that the front end of the TFT section gate electrode 66 extends (juts out) beyond the periphery of the a-Si layer 68.

Next, the following will explain the case where a positive potential is applied to the gate electrode 13. When a gate electrode 13 is supplied with a positive potential, the electrons in the n+ layer 69 are attracted to the potential of the TFT section gate electrode 66, and therefore carriers exist in the channel section. Therefore, a current can easily flow between the source and drain electrodes, and the TFT is turned on. As one example of this case, a voltage of 10V was applied to the gate electrode. As a result, a current of approximately 1 μA flows between the source and drain electrodes. Here, the voltage applied between the source and drain electrodes was 10V. Since the electrons have a behavior to flow in the shortest route between the source and drain electrodes when the TFT is ON, the TFT section gate electrode 66 is not required to penetrate through the semiconductor pattern.

However, there arises a problem when the a-Si layer 68 is not balanced with respect to the TFT section gate electrode 66, as shown in FIG. 13. Particularly, in the state shown in FIG. 13, the drain electrode 18 overlaps with the a-Si layer 68 only in a portion in the width direction. In this case, the flow of electrons are not sufficiently obtained in the source electrode 17, and therefore, the ON current increases or decreases in proportion to the width of the portion of the drain electrode 18 which overlaps with the a-Si layer 68. When having a plurality of such TFTs, the liquid crystal panel has variation of charging condition of each pixel, thus causing unevenness of the image. For this reason, the source electrode 17 and the drain electrode 18 are both required to overlap with the a-Si layer 68, by their whole widths.

In this view, in the step for providing the resist layer 67 to be used for processing the a-Si layer 68, by dropping the resist material from the inkjet head 33 of a pattern forming equipment, shooting error (dropping error in the dropping to a target dropping position), i.e., dropping accuracy needs to be taken into account so as to realize such an arrangement that the a-Si layer 68 entirely overlaps with the source electrode 17 and the drain electrode 18 in the channel section 72 and the front end portion of the TFT section gate electrode 66 is extending out of the a-Si layer 68.

Further, in order to create such an arrangement, the shooting error (dropping accuracy) upon dropping of the resist material from the inkjet head 33 of a pattern forming equipment, or more specifically, the dropping accuracy (±10 μm, for example) of a pattern forming equipment with respect to the diameter (30 μm, for example) of the resist layer 67, needs to be taken into account so as to provide a sufficient length to the TFT section gate electrode 66 so that the front end portion extends out of the a-Si layer 68.

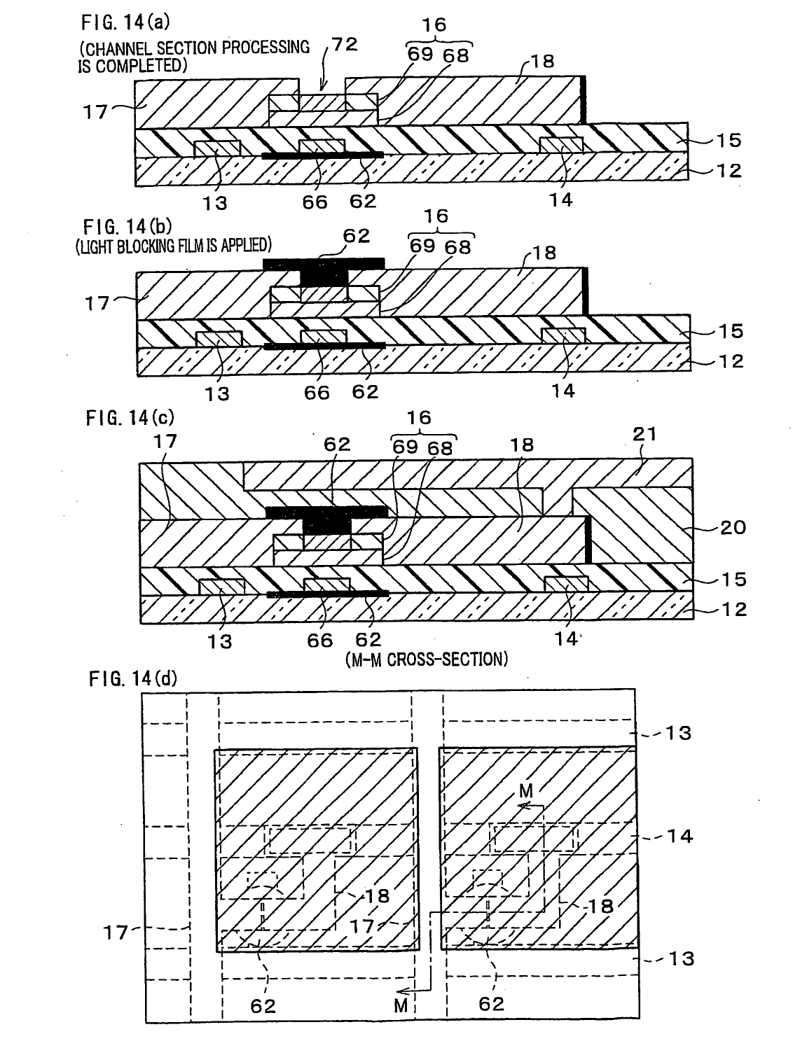

Note that, in the example above, the light blocking film (light blocking layer) 62 is formed on a lower portion of the TFT section 22 (in a lower layer than the semiconductor layer 16); however, the light blocking film 62 may be formed on an upper portion of the TFT section 22 (in an upper layer than the semiconductor layer 16). Here, the following will explain the case where the light blocking film 62 is formed on an upper portion of the TFT section 22, with reference to FIGS. 14(a) through 14(d). FIG. 14(a) is a vertical cross-sectional view showing the TFT array substrate 11 after the partial oxidation treatment of the channel section 72 is completed, and FIG. 14(b) is a vertical cross-sectional view of the TFT array substrate 11 showing the step for forming a light blocking film 62 on an upper portion, and FIG. 14(c) is a cross-sectional view, taken along the lines M-M of FIG. 14(d), and FIG. 14(d) is a plan view of the TFT array substrate 11 having the upper light blocking film 62 and showing a state where forming of a pixel electrode 21 is completed.

As explained in the Gate line pre-processing step 41, the light blocking film 62 is optional. For a particular example, a light blocking film 62 formed on an upper layer than the channel section 72 can prevent deterioration of the TFT characteristic, which is caused by unwanted light from the channel section 72. In the following example, the light blocking film is formed both on a lower portion and an upper portion of the TFT section 22. As circumstances demand, the TFT section 22 may include one or both of the upper and lower light blocking films 62.

After the partial oxidation treatment of the channel section 72 is completed as shown in FIG. 14(a), an upper light blocking film 62 is formed by dropping a droplet of a light blocking film material with a pattern forming equipment, as shown in FIG. 14(b). Thereafter, a photosensitive acrylic resin layer 20 is formed, and further, the pixel electrode 21 is formed, as shown in FIG. 14(c).

The material of the upper light blocking film 62 may be a resin mixed with TiN, as with the lower light blocking film 62 formed under the gate electrode 13 (TFT section gate electrode 66). Note that, since the light blocking film 62 is formed on an electrode in this example, it is preferable that the light blocking film 62 is made of an insulation material, and does not include components causing deterioration of performance of the semiconductor layer 16 by diffusing in the semiconductor layer 16.

Further, the light blocking film 62 may be formed between a protection layer (not shown) on the TFT and the photosensitive acrylic resin layer 20. This structure provides such an advantage that, since an inter-layer insulation layer is provided between the source and drain electrodes 17 and 18, and the light blocking film 62, the material of the light blocking film 62 is not required to be an insulator, or not required to be decided in consideration of the diffusion of the components in the semiconductor layer, thus widening the choice of materials. Further, in this case, since the photosensitive acrylic resin layer 20, which is used for forming the pixel electrode 21 (ITO electrode), is formed after the light blocking film 62, the level difference which occurs upon forming of the light blocking film 62 can be flattened by providing the photosensitive acrylic resin layer 20 thereon. Therefore, the thickness of the liquid crystal layer becomes even, and prevents occurrence of unevenness of the display. Further, the light blocking film 62 may be formed before applying ITO to form the pixel electrode 21, i.e., it may be formed between the photosensitive acrylic resin layer 20 and the pixel electrode 21.

As described, compared to a conventional manufacturing method without an inkjet type pattern forming equipment, the manufacturing method of a TFT array substrate 11 according to the present invention can reduce the number of masks from 5 to 3, thus reducing photolithography processes and number of vacuum deposition devices. On this account, equipment outlay can also be greatly reduced.

### Second Embodiment

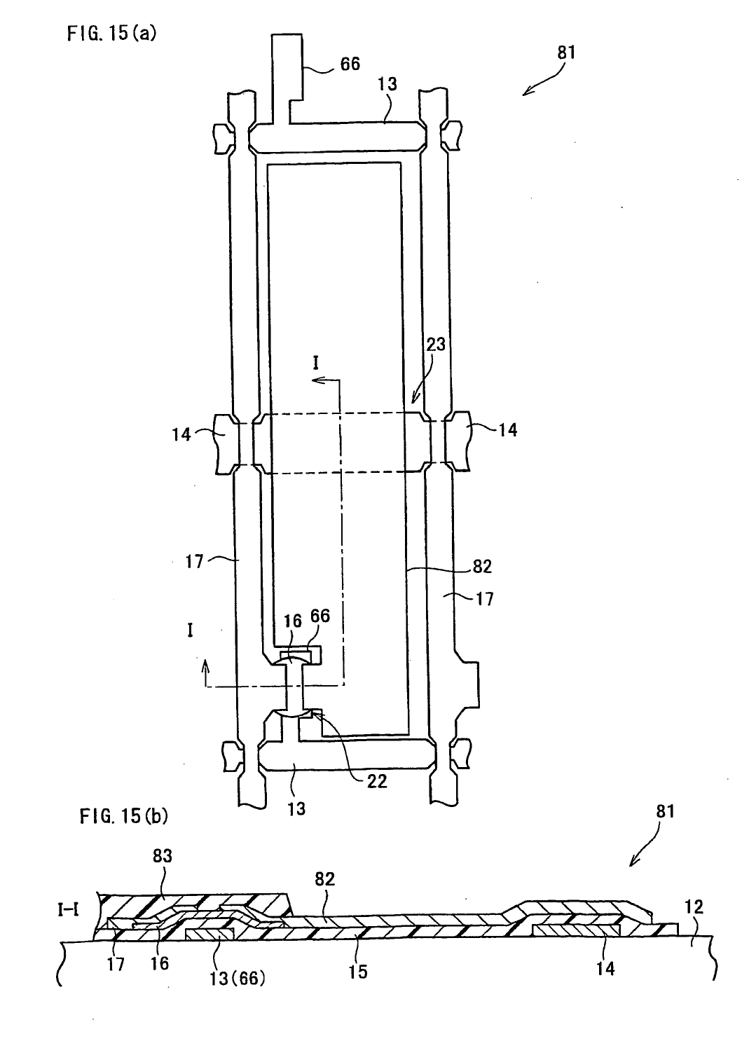

Another Embodiment of the present invention is described below with reference to FIGS. 15 through 21.

A liquid crystal display device according to the present Embodiment includes a pixel shown in FIG. 15(a). Note that, FIG. 15(a) is a plan view showing a schematic configuration of a pixel of a TFT array substrate. Further, FIG. 15(b) is a cross-sectional view, taken along the line I-I of FIG. 15(a).

In the TFT array substrate 11 shown in FIGS. 1(a) and 1(b), the passivation film 19 is formed after the source and drain electrodes 17 and 18, and thereafter, a guide for the pixel electrode is formed by the photosensitive acrylic resin layer 20.

In manufacturing of a TFT array substrate 81 to be used for a liquid crystal display device according to the present Embodiment, the source electrode 17 and a drain/pixel electrode 82 are formed on the same layer in either of a guide forming process or hydrophilic/hydrophobic process using a photocatalyst, which are carried out as one manufacturing step. Note that, in the TFT array substrate 81, the drain electrode and the pixel electrode are made of one continuous electrode, and therefore referred to as a drain/pixel electrode 82. Further, the passivation film 83 is formed substantially only on the TFT section 22.

Due to such differences in structure and manufacturing method, the TFT array substrate 11, on one hand, requires a mask in the manufacturing to form the photosensitive acrylic resin layer 20; and the TFT array substrate 81, on the other hand, does not require in the same step, thus requiring a less number of masks. However, in the manufacturing of the TFT array substrate 81, a guide for the pixel electrode (drain/pixel electrode 82) or the hydrophilic/hydrophobic area is formed in the same step for forming a guide for the source electrode 17. Thus, the TFT array substrate 81 has a smaller aperture ratio than that of the TFT array substrate 11.

Further, in the TFT array substrate 11, the pixel electrode 21 and an storage capacitor electrode 14 are formed as separate layers. Therefore, the drain electrode 18 extends to the storage capacitor section 23, and the contact hole 24 is formed above the storage capacitor section 23 so as to conduct the drain electrode 18 to the pixel electrode 21. On the other hand, in the TFT array substrate 81, the drain/pixel electrode 82 is provided also as an electrode extending to the storage capacitor section 23.

In both the TFT array substrates 11 and 81, in order to prevent the materials of the source electrode and the pixel electrode from splashing to the channel section 72, the source and drain electrodes are formed by dropping the electrode material from the inkjet head 33 to a portion away from the channel section 72. Also, the area for the source and drain electrodes is formed in a taper shape becoming wider toward the channel section 72 so that the electrode material flows toward the channel section 72. An example of this shape is plainly shown in the vicinity of the channel in the drain electrode 18 and the source electrode in FIG. 1(a).

Further, the a-Si layer 68 may be formed by processing the a-Si forming layer 64 by using a mask, i.e., by using the resist layer 67 formed by a single (one shot) droplet; however, for a structure including a long TFT extending in parallel to the source electrode 17, the resist layer 67 may be formed by two or more droplets (two or more shots) of the material.

Next, the following will explain a manufacturing method of the TFT array substrate 81 including a TFT, used for a liquid crystal display device according to the present embodiment.

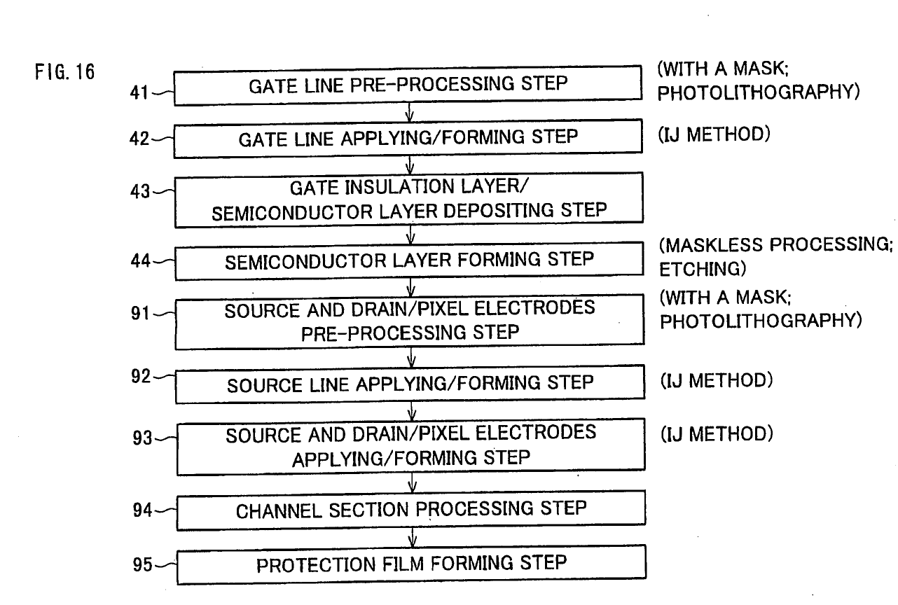

In the present Embodiment, the TFT array substrate 81 is manufactured through, as shown in FIG. 16, a gate line pre-processing step 41, a gate line applying/forming step 42, a gate insulation layer/semiconductor layer depositing step 43, a semiconductor layer forming step 44, a source and drain/pixel electrodes pre-processing step 91, a source line applying/forming step 92, a drain/pixel electrode applying/forming step 93, a channel section processing step 94, a passivation film forming step 95. The gate line pre-processing step 41 through the semiconductor layer forming step 44 are the same as those in manufacturing of the TFT array substrate 11, and therefore explanations thereof will be omitted here.

[Source and Drain/Pixel Electrodes Pre-Processing Step 91]

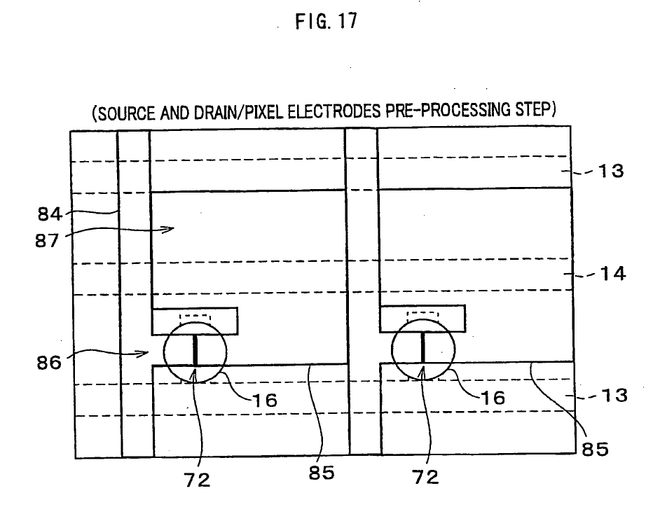

FIG. 17 shows the source and drain/pixel electrodes pre-processing step 91. FIG. 17 is a plan view showing the glass substrate 12 after the semiconductor layer forming step, i.e., the glass substrate 12 provided with a wiring guide 84 for forming the source electrode 17 and a wiring guide 85 for forming the drain/pixel electrodes 82.

In this step, the wiring guide 84 is formed on an area for forming the source electrode 17 (source forming area 86), and the wiring guide 85 is formed in an area for forming the drain/pixel electrodes 82 (drain/pixel electrodes forming area 87). In this Embodiment, the wiring guides 84 and 85 were formed by a photoresist material. More specifically, the glass substrate 12 after the semiconductor layer forming step 44 was coated with a photoresist, and was subjected to pre-baking, and then developed by exposure using a photo mask, and further subjected to post-baking. Each of the wiring guides 84 and 85 thus created had a width=10 μm, and the width of the groove (the width of the wiring forming area) created with the wiring guide 84 was approximately 15 μm. Note that, the interval between the source and drain electrodes, i.e., the channel section 72 was set to 4 μm.

Note that, here, the glass substrate 12 may be arranged such that the SiNx surface (the upper surface of the gate insulation layer 15) is processed to be provided with hydrophilicity by using an oxygen plasma, and the wiring guides 84 and 85 are processed to be provided with water-repellence by supplying CF₄ plasma, so that the wiring material from a pattern forming equipment can be smoothly applied to the base surface.

Further, instead of forming the wiring guides 84 and 85, the glass substrate 12 may be subjected to the hydrophilic/hydrophobic processing using a photocatalyst according to the pattern of wiring electrode, as with the foregoing gate electrode forming step. Note that, in this case, a particular care is required to prevent the material of the source electrode from being splashing to the pixel electrode.

[Source Line Applying/Forming Step 92]

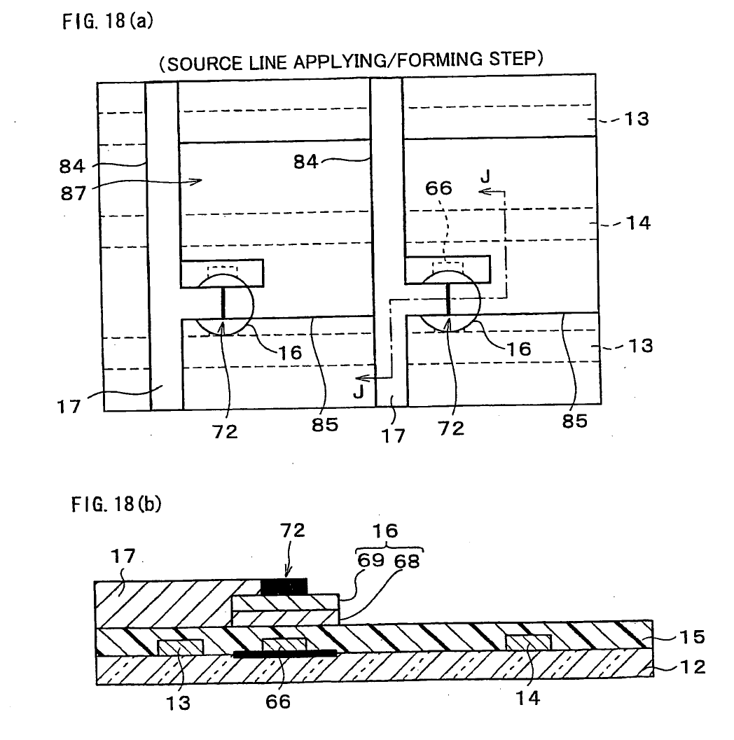

FIGS. 18(a) and 18(b) show the source line applying/forming step 92. FIG. 18(a) is a plan view showing the source electrode 17 which has been formed along the wiring guide 84. FIG. 18(b) is a cross-sectional view, taken along the line J-J of FIG. 18(a).

As shown in FIGS. 18(a) and 18(b), in this source line applying/forming step 92, the source electrode 17 was formed by coating the source forming area 86, which is formed by the wiring guide 84, with a wiring material by using a pattern forming equipment. Here, the discharging amount of the wiring material from the inkjet head 33 was set to 2 pl. Further, Ag particles are used as the wiring material, and the thickness of the electrode was adjusted to 0.3 μm. Further, baking temperature was 200° C., and after the baking, the wiring guide 84 was removed by an organic solvent.

Note that, in this step, the same wiring material may be used as the one used for the gate electrode 13; however, the baking temperature is required to be at or lower than 300° C., since the a-Si is formed at around 300° C.

[Drain/Pixel Electrode Applying/Forming Step 93]

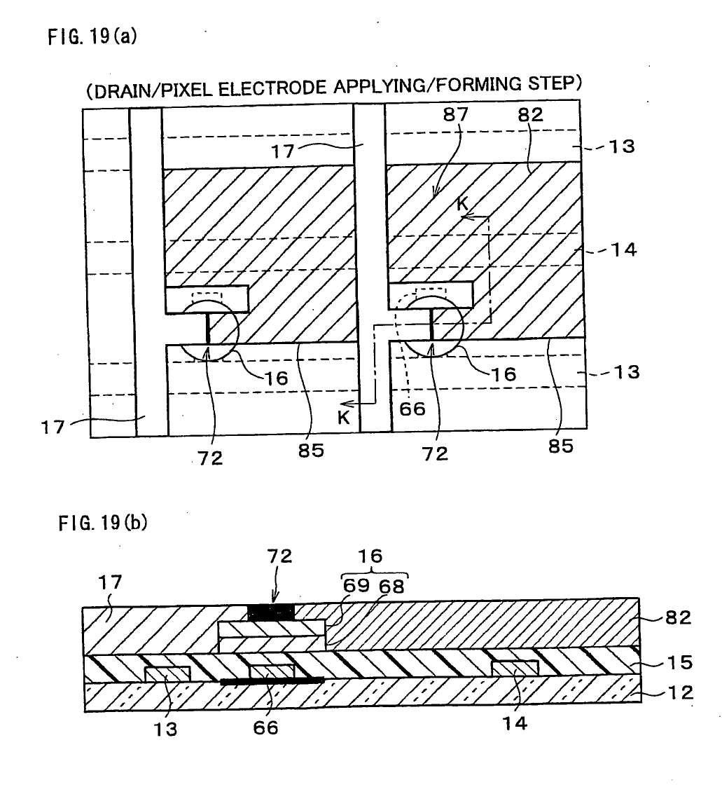

FIG. 19(a) and 19(b) show the drain/pixel electrode applying/forming step 93. FIG. 19(a) is a plan view showing the drain/pixel electrode 82 which has been formed along the wiring guide 85. FIG. 19(b) is a cross-sectional view, taken along the line K-K of FIG. 19(a).

In this drain/pixel electrode applying/forming step 93, the drain/pixel electrode 82 was formed by applying an ITO particle material to the wiring guide 85 by using a pattern forming equipment, and then was baked with a baking temperature of 200° C.

In this manner, only a single mask is required for the source/drain electrodes forming step and the ITO processing step, unlike the conventional method which uses respective masks for these steps. Further, the use of an inkjet type pattern forming equipment allows separate application of the electrode material and the pixel electrode material with respect to each pattern by using separate inkjet heads 33. Accordingly, the present method requires a simpler device system and improves efficiency of material use, thus realizing cost reduction.

[Channel Section Processing Step 94]

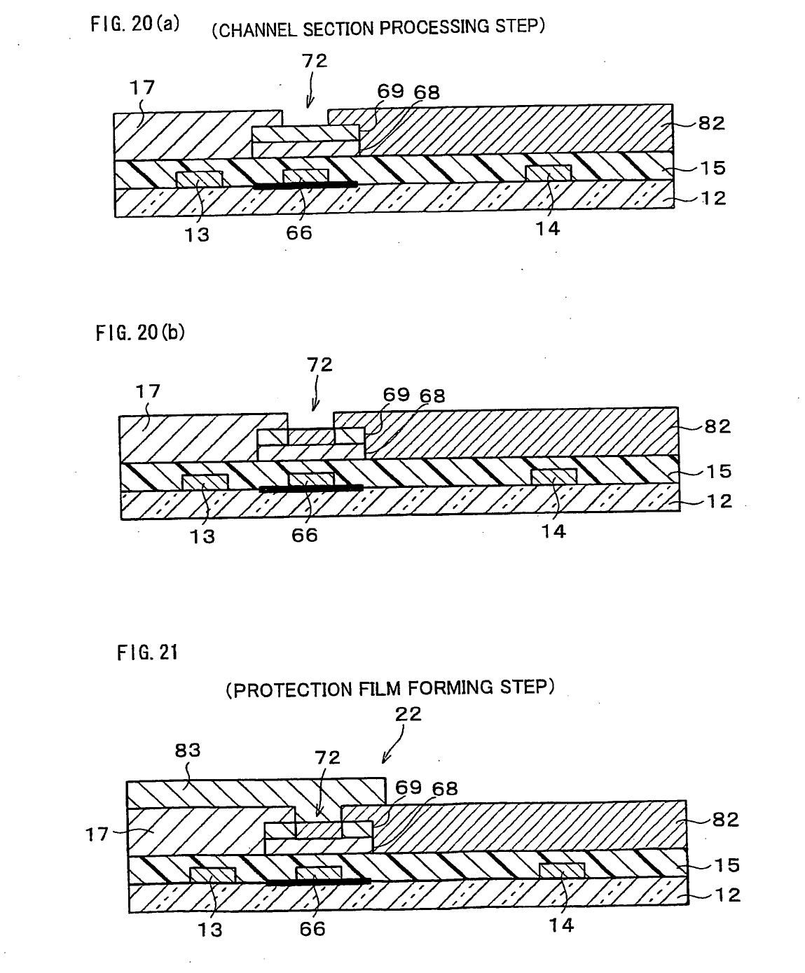

This step is carried out for processing the channel section 72 of the TFT. FIGS. 20(a) and 20(b) are cross-sectional views corresponding to a portion taken along the line K-K of FIG. 19(a). Firstly, as shown in FIG. 20(a), the wiring guides 84 and 85 of the channel section 72 were removed by an organic solvent or by ashing. Next, as shown in FIG. 20(b), the n+ layer 69 was subjected to oxidation treatment by ashing or by using a laser so as to be a nonconductor.

[Passivation Film Forming Step 95]

FIG. 21 shows the passivation film forming step 95. FIG. 19(a) is a cross-sectional view corresponding to a portion taken along the line K-K of FIG. 19(a). In this step, a passivation film 83 was formed by a pattern forming equipment on a glass substrate 12 which had been provided with the source electrode 17 and the drain/pixel electrode 82.

To create the passivation film 83, a transparent inorganic material such as an ethoxy silane material is applied on the TFT section 22, and then was baked with a temperature of approximately 150° C. The material of the passivation film 83 may also be a resist material or a photosensitive resin. Further, the light blocking film 62 may be used as the material which blocks external light and also operates as black matrix on a color filter. Namely, both a transparent material and an opaque material may be used as the material of the passivation film 83. Here, a TFT array substrate 81 is completed.

In comparison with the conventional manufacturing without an inkjet method, the number of masks may be reduced from 5 to 2 in the manufacturing steps of the present embodiment, and the source electrode 17 and the drain/pixel electrode 82 can be formed by one guide forming step. Therefore, the number of masks can further be reduced less than that of the manufacturing of the TFT array substrate 11.

Further, as with the manufacturing of the TFT array substrate 11, number of vacuum deposition equipments can be reduced.

Note that, the foregoing example uses a-Si for the semiconductor layer; however, an organic semiconductor or a particle type semiconductor material may also be used. In this case, a step for directly applying a semiconductor material from a pattern forming equipment is carried out instead of the processing step of a-Si of the TFT array substrate. Accordingly, application of a resist or resin material, dry etching, and removal process of the resist or resin material can be omitted, thereby further simplifying the manufacturing.

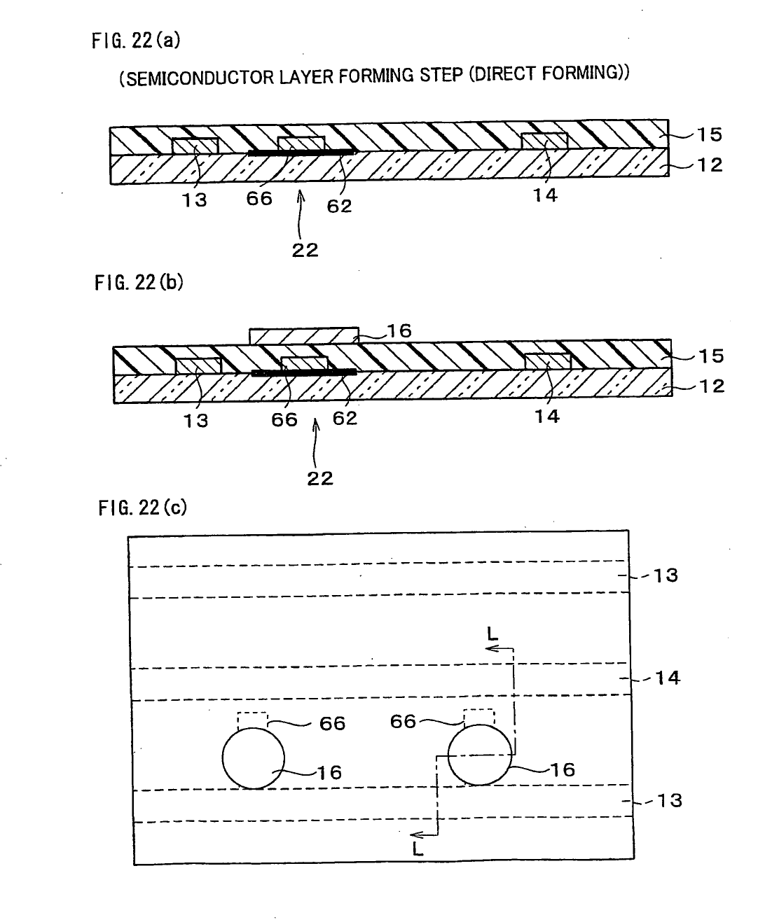

FIGS. 22(a) through 22(c) show a manufacturing method of the semiconductor layer 16 according to the foregoing manner.

In this manner, after forming the gate insulation layer 15, a semiconductor material is directly dropped from a pattern forming equipment onto the gate insulation layer 15 in the TFT section 22, and the material is then baked to create the semiconductor layer 16, as shown in FIGS. 22(b) and 22(c). In this example, an organic semiconductor material such as polyvinyl carbazole (PVK) or polyphenylene vinylene (PPV) may be used as the semiconductor material.

In contrast to an a-Si formed by a CVD, etching process is not necessary to the foregoing materials since they can be formed to be the semiconductor layer 16 with a droplet (1 shot) from a pattern forming equipment. Thus, hydrophilic/hydrophobic processing is not necessary in the area for forming the semiconductor layer 16, in this case.

The TFT array substrates 11 and 18 described in Embodiments 1 and 2 was arranged so that the gate electrode 13 includes the TFT section gate electrode 66, which is branched out from the main line of the gate electrode 13; and the TFT was formed on this TFT section gate electrode 66. In this example, the gate electrode 13 does not include a branch electrode (TFT section gate electrode 66).

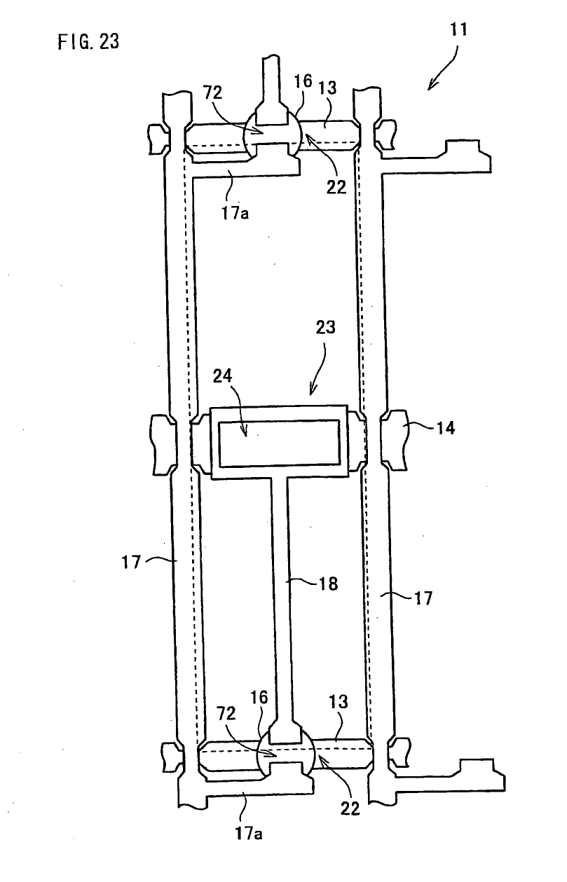

As shown in FIG. 23, the semiconductor layer 16 is formed on the gate electrode 13 (gate line), and a branch electrode 17a from the source electrode 17 extends to the channel section 72 (TFT section 72). Meanwhile, the drain electrode 18 linearly extends from the storage capacitor section 23 constituting the storage capacitor, and reaches to the channel section 72. Note that, this example has been explained as an arrangement compatible with the First Embodiment shown in FIG. 1; however, this example may also be adopted for the Second Embodiment shown in FIG. 15.

In the TFT array substrate 11 of this example, since the gate electrode 13 does not include a branch electrode, the foregoing arrangement with a branch electrode (TFT section gate electrode 66) penetrating through the semiconductor pattern is not necessary.

This arrangement of the TFT array substrate 11 is effective for a configuration where the gate electrode 13 has relatively narrow width, for example in a range between 10 μm and 20 μm. In a display panel of at or less than a range of 10-15 inches in diagonal screen measurement, the gate electrode 13 is formed with a relatively narrow width and short length. On the other hand, in a display panel of at or larger than 20 inches, the width of the gate electrode 13 becomes wider for reducing the resistance. If the present example is adopted in this case, the width of the gate electrode in the TFT forming area needs to be narrow. Namely, the present arrangement is effective in a case where the length of the TFT is substantially same as the width of the gate electrode.

Note that, since there also are influences of the resistance of materials and other design parameters, the foregoing relation between the size of the screen and the width of the gate electrode is not always true.

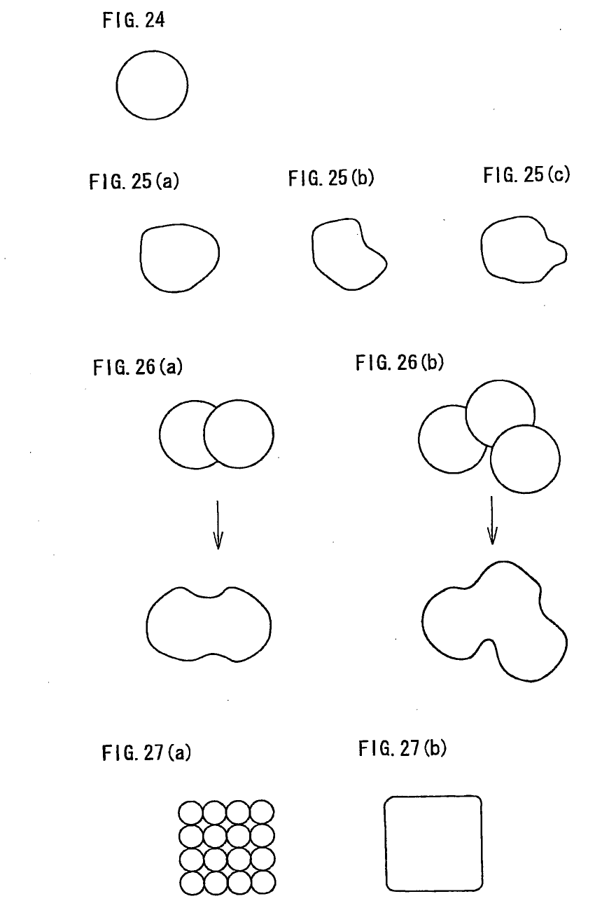

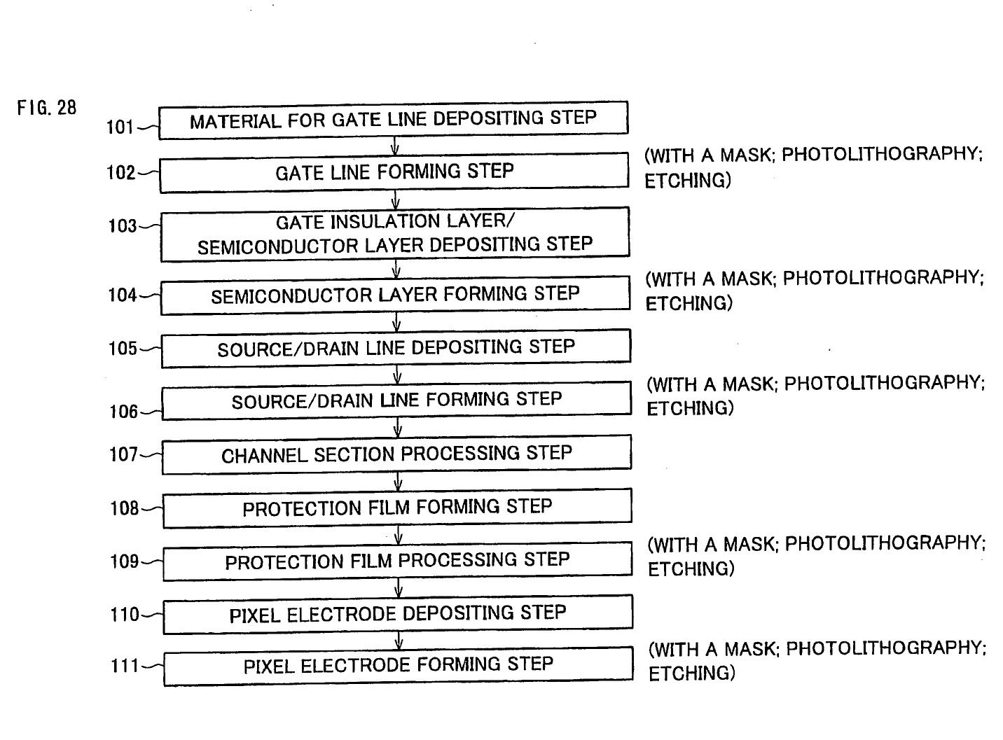

Further, in the foregoing explanation, the shape of the droplet refers to a state of a droplet when dropped from a pattern forming equipment. The contour of this shape has a curvature. Therefore, if only one droplet is dropped, or plural droplets are dropped onto the same position, the shape of the droplet becomes a circular or a substantially circular shape, as shown in FIG. 24.

Further, the shape of the droplet is not always a circular or a substantially circular shape but can be a deformed circular shape (a collapsed or distorted circle). For example, the shape may be a substantially circular shape deformed from a circle, as shown in FIG. 25(a), a shape having a concave portion, as shown in FIG. 25(b), a shape partly including a convex portion, as shown in FIG. 25(c). It is assumed that such a shape with a contour having a curvature is created due to delicate difference of surface condition of the substrate on which the droplet is dropped, or due to air resistance when the droplet splashes. The foregoing shapes all satisfy the regulation of the present invention for the shape of droplet, because they each are regarded immediate shapes created by dropping.

Further, the shape of droplet is not necessarily created by a single droplet but by plural droplets. FIG. 26(a) shows a case where a deformed oval shape is formed by two droplets. The respective droplets merge as a result of dropping, or merge into a contour after dropping, and result in a shape with a contour having a curvature. FIG. 26(b) shows an example formed by three droplets.

It should be noted that the present example do not intend the state shown in FIG. 27(a) where a plural of infinitesimal droplets are applied, which results in the shape shown in FIG. 27(b).

As stated above with reference to FIGS. 1(a) and 15(a), the liquid crystal display device according to the present invention has a TFT section 22 with the TFT section gate electrode 66 of the gate electrode 13 penetrating through the semiconductor pattern (semiconductor layer 16) having substantially a circular shape, so as to prevent a leak current flowing between the source and drain electrodes when the gate is OFF.

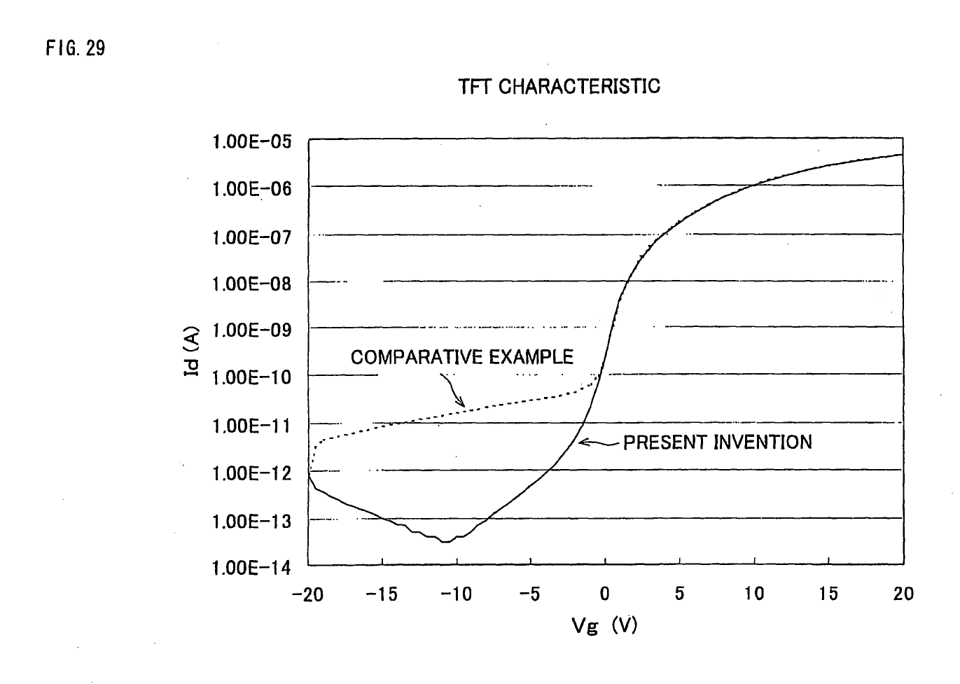

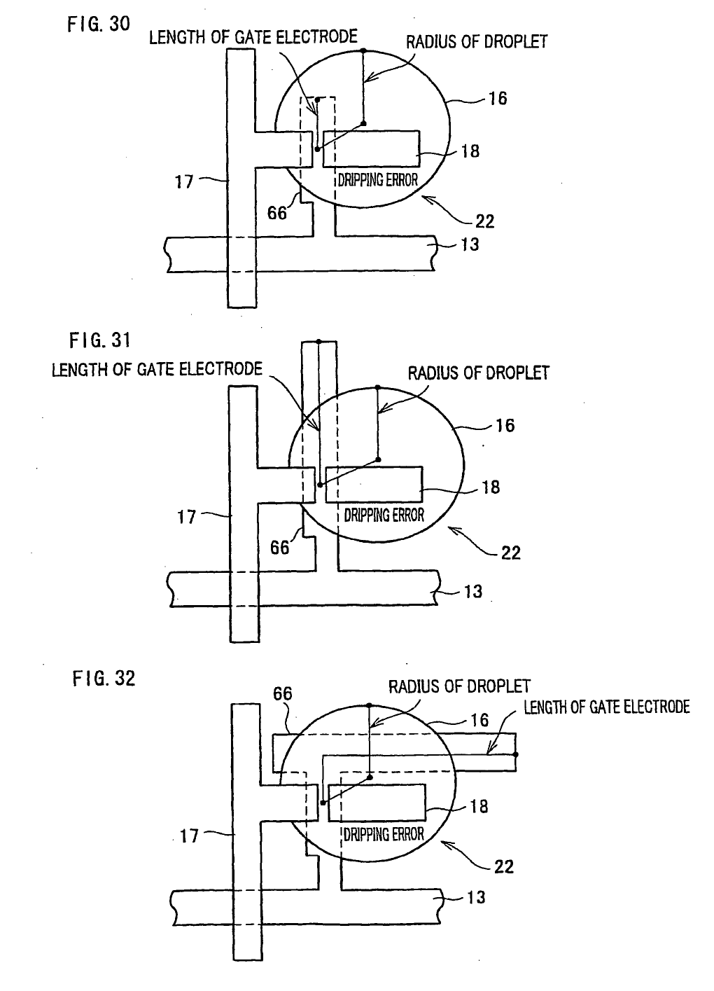

More specifically, the characteristic of the TFT section 22 of the liquid crystal display device of the present invention can be expressed as the relation between the drain current (Id) and the gate voltage (Vg) shown in FIG. 29. Note that, the graph in FIG. 29 uses a TFT (shown in FIG. 30) as a comparative example, with the TFT section gate electrode 66 of the gate electrode 13 not penetrating through the semiconductor layer 16 due to shooting error of the droplet upon forming of the semiconductor layer.

As can be seen in FIG. 29, when the gate voltage has a negative value, i.e., the gate is OFF, the drain current seldom flows in the TFT of the present invention; in contrast, the drain current slightly flows in the TFT shown in FIG. 30. Specifically, when the gate is OFF, the drain current (leak current) seldom flows in the TFT of the present invention but slightly flows in the TFT shown in FIG. 30.

Note that, the direction for the TFT section gate electrode 66 to penetrate through the semiconductor layer 16 is not limited. For example, the TFT section gate electrode 66 may penetrate along the source electrode 17, as shown in FIG. 31, or may penetrate along the drain electrode 18, as shown in FIG. 32.

In the foregoing arrangement with the TFT section gate electrode 66 penetrating through the semiconductor layer 16 so as to prevent a leak current between the source and drain electrodes when the gate is OFF, the larger quantity of penetration is preferable when considering a shooting error, because it makes it easier to appropriately shoot a droplet upon forming of the semiconductor layer 16, so that a leak current can be prevented. However, when adopting the TFT for a liquid crystal display device, particularly in a transmissive liquid crystal display device, there arises a problem of a decrease of aperture ratio. Note that, the decrease of aperture ratio does not occur in case of a reflective liquid crystal display device.

In view of this problem, the following will explain an Embodiment as an example of fabrication of a semiconductor layer, in which a droplet is applied in a certain position, so as to create a semiconductor layer not causing a leak current while also preventing a decrease of aperture ratio.

### Third Embodiment

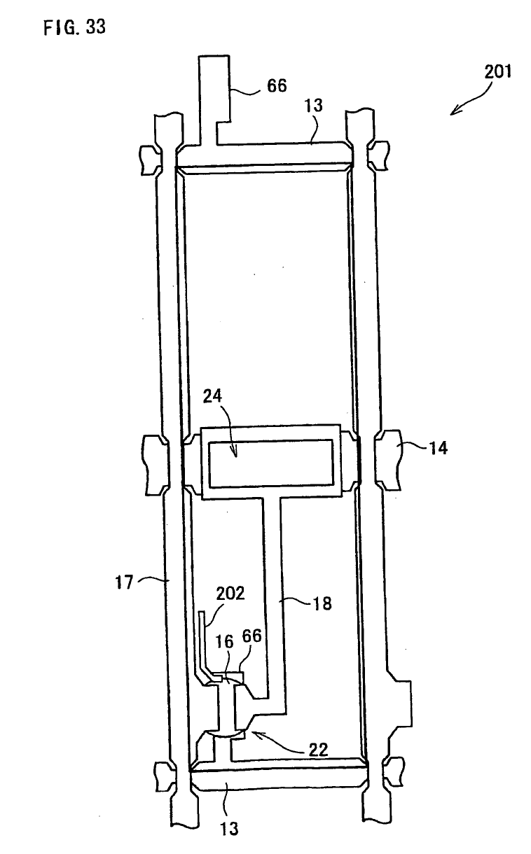

Still another Embodiment of the present invention is described below with reference to FIGS. 33 through 36.

A liquid crystal display device according to the present Embodiment includes a pixel shown in FIG. 33. FIG. 30 is a plan view showing a schematic configuration of a pixel of a TFT array substrate. Further, this pixel is the same as that shown in FIG. 1(a), which is used for a transmissive liquid crystal display device. For ease of explanation, materials having the equivalent functions as those shown in the drawings pertaining to FIG. 1(a) will be given the same reference symbols, and explanation thereof will be omitted here.

As shown in FIG. 33, a TFT array substrate 201 according to the present Embodiment has substantially the same configuration as that of the TFT array substrate 11 shown in FIG. 1(a) except for a protrusion electrode 202 extending from an end of the TFT section gate electrode 66, and is provided in contact with the source electrode 17.

The protrusion electrode 202 has a narrower width than that of the TFT section gate electrode 66 and provided in contact with the source electrode 17.

With this configuration, the aperture ratio of the TFT array substrate 201 does not decrease even in the case where the semiconductor layer 16 has the configuration to prevent a leak current between the source and drain electrodes when the gate is OFF.

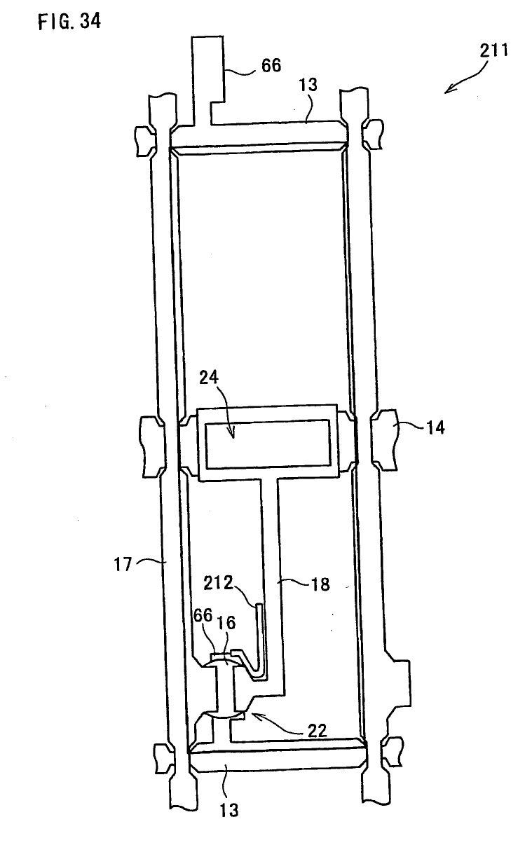

Further, FIG. 34 shows a TFT array substrate 211 as another possible example, in which a protrusion electrode 212 extending from an end of the TFT section gate electrode 66 is provided in contact with the drain electrode 18.

As with the case above, this configuration does not cause the decrease of aperture ratio of the TFT array substrate 211 even in the case where the semiconductor layer 16 has the configuration to prevent a leak current between the source and drain electrodes when the gate is OFF.

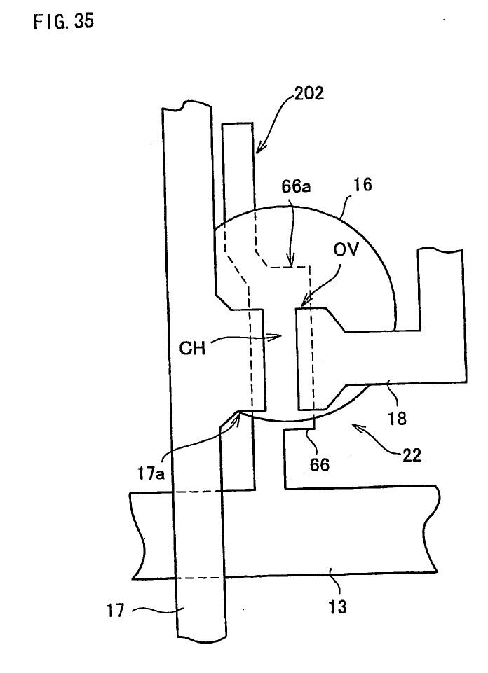

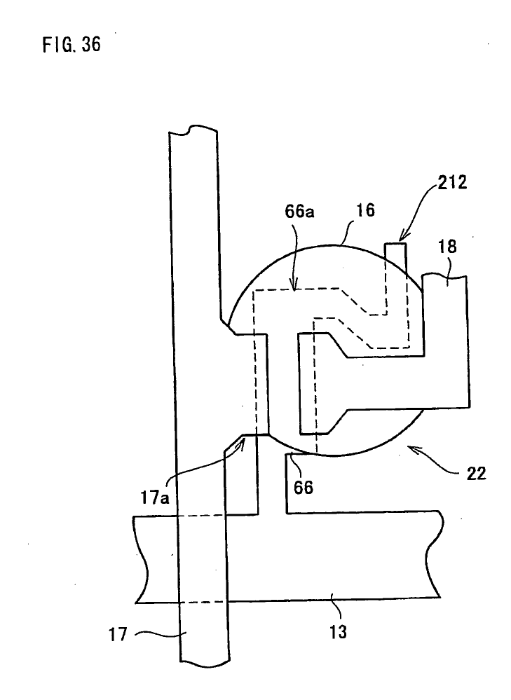

Here, the following will minutely explain a configuration in the vicinity of the TFT section 22 with reference to FIGS. 35 and 36.

FIG. 35 is a magnified view in the vicinity of the TFT section 22 of the TFT array substrate 201 shown in FIG. 33, in which the protrusion electrode 202 extends along the source electrode 17. Further, FIG. 36 is a magnified view in the vicinity of the TFT section 22 of the TFT array substrate 211 shown in FIG. 34, in which the protrusion electrode 212 extends along the drain electrode 18.

As shown in FIG. 35, a protrusion electrode 202 extends from an end portion 66a of the TFT section gate electrode 66, and the width of the protrude electrode 202 is set narrower than that of the end portion 66a.

Note that, in the present Embodiment, the width of the end portion 66a of the TFT section gate electrode 66 is set to 10 μm, the width of the protrusion electrode 202 is set to 5 μm, the distance between the source and drain electrodes 17 and 18, i.e., the channel length of TFT CH is set to 5 μm.

Further, the TFT section gate electrode 66 generally has a wider width than that of the TFT length CH, and is provided with a portion OV (overlapping portion) where the source electrode 17 and the drain electrode 18 are overlapped with each other. Therefore, as with the present Embodiment, the channel length of TFT CH of 5 μm requires the width of the TFT section gate electrode 66 to be approximately 10 μm.

Note that, the value specified here is only an example, and present invention is not limited to this value.

Further, an end portion of the protrusion electrode 202 has to be out of the semiconductor layer 16 (a-Si layer); however, the width of the end portion of the protrusion electrode 202 is not restricted by the TFT length CH.

More specifically, the end portion of the protrusion electrode 202 extends out of the semiconductor layer 16 so that a leak current does not flow from the source electrode 17 to the drain electrode 18 when the TFT section gate electrode 66 becomes OFF state by being supplied with a voltage. Therefore, the end portion of the protrusion electrode 202 is not required to have the same width as that of the end portion 66a of the TFT section gate electrode 66.

Accordingly, since the end portion of the protrusion electrode 202 may be provided with a narrower width than that of the end portion 66a of the TFT section gate electrode 66, the protrusion electrode 202 can be disposed closely along the source electrode 17, as shown in FIGS. 33 and 35, thereby preventing the decrease of aperture ratio of the TFT array substrate 201.

However, it should be noted that, it is preferable that the protrusion electrode 202 is not overlapped with the source electrode 17. If the protrusion electrode 202 and the source electrode 17 are overlapped with each other, a new capacitance is generated between the protrusion electrode 202 and the source electrode 17 via the gate insulation layer (not shown), and causes delay or blunt waveform of the signal flowing in the source electrode 17.

Here, the semiconductor layer 16 shown in FIG. 35 is formed by a droplet which has been applied on a portion upper in the figure than the target position (the center of the source and drain electrodes).

Incidentally, when the border line (outline of the circular arc) of the semiconductor layer 16 is shifted upper than an end face 17a of the source electrode 17, the effective width of the TFT becomes narrower. Accordingly, when the semiconductor layer 16 is formed with an upper border line than that in FIG. 35, the characteristic of the TFT decreases.

Thus, the border line of the semiconductor layer 16 is preferably lower than the end face 17a of the source electrode 17.

Meanwhile, the upper end of the semiconductor layer 16 (the border area near the end portion 66a of the TFT section gate electrode 66) extends far beyond the end portion 66a of the TFT section gate electrode 66, and disposed above the figure. Here, if the protrusion electrode 202 is not provided on the end portion 66a of the TFT section gate electrode 66, the semiconductor layer 16 extending beyond the end portion 66a of the TFT section gate electrode 66 causes a leak current between the source and drain electrodes. More specifically, there arises a decrease of the characteristic of the TFT section 22.

In such a case, the end portion 66a of the TFT section gate electrode 66 is required to be further extended; however, when the end portion 66a extends upward in the figure with the same width, it invades the pixel area of the TFT array substrate 201.

In this view, as shown in FIG. 35, the protrusion electrode 202 is extended along the source electrode 17 with a narrower width than that of the end portion 66a of the TFT section gate electrode 66, thus preventing the decrease of the aperture ratio of the pixel section in the TFT section gate electrode 66.

Further, in the example of FIG. 35, the upper end of the protrusion electrode 202 is far beyond the border area of the semiconductor layer 16, and therefore a leak current does not occur. In this way, it is possible to prevent the decrease of the characteristic of the TFT section 22. Besides, the characteristic of the TFT section can further be improved.

Further, as with the protrusion electrode 212 shown in FIG. 36, it may be formed by extending from the end portion 66a of the TFT section gate electrode 66 along the drain electrode 18. The protrusion electrode 212 is extended not upward in the figure, i.e., along the source electrode 17 but along the drain electrode 18. As with the protrusion electrode 202, the width of the protrusion electrode 212 is narrower than that of the end portion 66a of the TFT section gate electrode 66.

FIG. 36 shows the semiconductor layer 16 shifted to the right of the figure. In this example, the end face 17a of the source electrode 17 comes right on the border of the semiconductor layer 16, and therefore the semiconductor layer 16 is no longer allowed to be shifted upward or to the right of the figure. Here, the upper end portion of the protrusion electrode 212 needs to be out of the semiconductor layer 16.

Since the protrusion electrode 212 extends along the drain electrode 18, it is possible to prevent the decrease of the aperture ratio of the pixel section in the TFT array substrate 211. However, the protrusion electrode 212 should not be overlapped with the drain electrode 18 so as to prevent generation of the capacitance which draws a charge to the pixel section and causes undercharge.

Note that, it is preferable for both the protrusion electrode 202 and the protrusion electrode 212 not to be overlapped with the source electrode 17 or the drain electrode 18; however, when the overlapping occurs, the charging of the pixel section can be adjusted in consideration of the capacitance, by controlling a signal flowing to each electrode.

The present Embodiment has explained an example of providing the protrusion electrode 202 along the source electrode 17 as shown in FIG. 33, and an example of providing the protrusion electrode 212 along the drain electrode 18 as shown in FIG. 34. Such configuration can prevent a leak current between the source electrode 17 and the drain electrode 18 when the TFT section gate electrode 66 in the TFT section 22 becomes OFF state by being supplied with a voltage, while preventing the decrease of the aperture ratio of the pixel section in the TFT array substrate.

In other words, the Third Embodiment has explained the forming directions of the protrusion electrode 202 and the protrusion electrode 212 which extend from the end portion 66a of the TFT section gate electrode 66.

The following Fourth Embodiment describes the extent to which the end portion 66a of the TFT section gate electrode 66 protrudes from the semiconductor layer 16.

### Fourth Embodiment

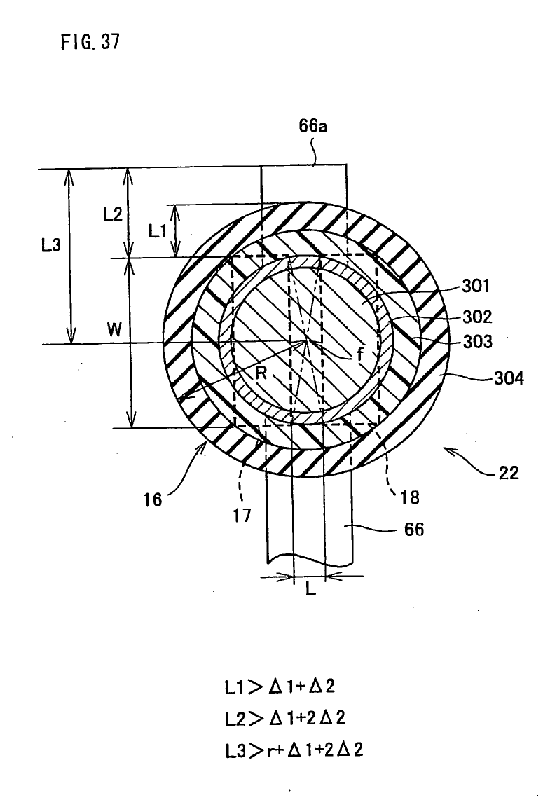

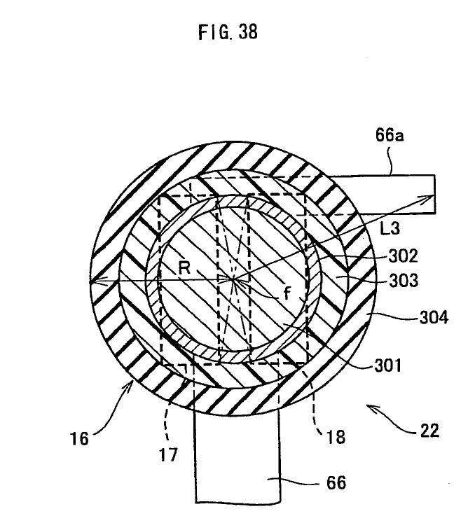

Yet another Embodiment of the present invention is described below with reference to FIGS. 37 and 38.

The present Embodiment explains an example of forming a TFT by an inkjet method while taking account of shooting error of a droplet.

Firstly, the following will discuss the shooting error of a droplet. The shooting error occurs depending on where the droplet lands in and how the droplet spreads. Here, the shooting error is discussed in view of two factors. The first is the occupied area of the droplet after discharged, which depends on the amount of liquid and the way it spreads. The second is dropping off the target position.

Depending on unevenness of discharge amount of the droplet, or surface condition of the substrate (hydrophilic or hydrophobic), the first factor may include unpredictability of the shape of the droplet area.

Here, the unpredictability of the shape of the droplet area refers to variation of the outline of the applied droplet. This variation results from unevenness of the spread of liquid due to difference in drop condition. The unpredictability occurs even when the discharge is performed with a predetermined amount of liquid in order to create a an application area of desirable size which takes account of the wettability of the substrate, which depends on the processing of the discharging surface and droplet material.

The second factor includes such as mechanical error, i.e., positioning accuracy of the stage, inkjet head nozzle processing error, variation of dimension or shape of multi-nozzles, the difference of distance between substrate and nozzles, error caused by thermal expansion of the inkjet head. Further, it also relates to variation of ink discharging direction which is caused by deposits in the nozzle which changing wetting condition of the nozzle surface with ink.

The dropping accuracy of the inkjet also relates to many other complicated factors; however, the present Embodiment will be explained based on the foregoing two factors.

In the TFT shown in FIG. 37, the target dropping position is the center of the channel section 72. The range of dropping error is denoted by a circle 301 whose radius=Δ2, which is equal to the distance from the target position. Here, Δ2 denotes an error due to dropping off the target position (stage error+mechanical processing error+dropping angle error+thermal expansion+ . . . ). More specifically, the center of the droplet after the dropping will be within the circle having the radius R=Δ2, as shown in FIG. 37, where Δ2 denotes the error of dropping off the target dropping position, which is caused by the mechanical error or condition of the nozzle (the second error taking account of dropping off the target position).

Further, the minimum range of area required to be covered by the a-Si area (semiconductor layer 16), which is processed by a resist (droplet) applied from an inkjet method, is shown by the width W and the length L in the channel section of the TFT. Accordingly, assuming that the droplet discharged from the inkjet forms a circle, the circle (the circle 302 in the figure) has the radius r from the center f of the channel section. Here, the radius r denotes the distance from the center of the TFT (the center f of the channel section) to the end of the channel section. In other words, the radius r denotes the distance from the center of the channel section to the outermost end of the channel section.

The circle 303 in the same figure has a larger radius R=r+Δ1 by taking account of error caused by variation of liquid amount and variation of the way the droplet spreads, i.e., taking account of an error of the radius depending on the amount of liquid, and unpredictability of the spread shape of the liquid. Here, Δ1 denotes an error taking account of variation of liquid amount+variation of the spread (error of the spread). More specifically, Δ1 denotes the first error taking account of variation of discharging amount of the droplet and variation of the spread of the droplet after the discharge, upon forming of the semiconductor layer.

Accordingly, when the droplet is dropped into the center of the channel section, the channel section can be covered if the discharging amount of the droplet is adjusted to form the circle 303 having the radius=r+Δ1 taking account of unpredictability of the amount of the liquid and the area of the droplet.

Further, also considering the dropping position error Δ2, the circle 304 with a radius=r+Δ1+Δ2 denotes a required radius for covering the channel section, when the discharge is carried out with respect to the center f of the channel section.

Accordingly, the semiconductor layer 6 after processing preferably has the radius R given by the following formula (3).
R>r+Δ1+Δ2 (3)

In FIG. 37, the border of the semiconductor layer 6 is denoted by the distance L1 which extends from the upper ends of the source and drain electrodes 17 and 18 (the end portion near the end portion 66a of the TFT section gate electrode 66).

Thus, when the semiconductor layer 6 is processed by discharging a droplet of resist with respect to the center of the TFT channel section, the distance L1 extending from the upper ends of the source and drain electrodes 17 and 18 preferably satisfies the following formula (4).
L1>Δ1+Δ2 (4)

Note that, the width W of the channel section of the TFT section 22 is longer than the length L in this case, and therefore the length L is extremely short. Thus, this example applies the condition of W/2≈r.

Since the circle 304 with the radius R≈r+Δ1+Δ2 extends toward the end portion 66a by the error Δ2 from the target dropping position, the end portion 66a, which is the open end portion of the TFT section gate electrode 66, is preferably provided according to the following formula (1),
L3>r+Δ1+2Δ2 (1)

where L3 expresses the distance from the center f of the channel section to the end portion 66a.

Further, the distance L2 from the end portions of the source and drain electrodes 17 and 18 to the end portion 66a preferably satisfies the following formula (2), where w/2≈r.
L2>Δ1+2Δ2 (2)

In this figure, Δ2 is multiplied by 2 taking account of both plus direction and minus direction of the error.

Note that, the condition for determining the position of the end portion 66a of the TFT section gate electrode 66 may be given by either of the foregoing formulas (1) and (2).

FIG. 38 shows the end portion 66a of the TFT section gate electrode 66 bending to the right of the figure. In this case, the position of the end portion 66a of the TFT section gate electrode 66 cannot be restricted by the distance from the end portions of the source and drain electrodes 17 and 18; thus, the position is restricted by the distance from the center f of the channel section. In this case, the position of front end of the end portion 66a of the TFT section gate electrode 66 is preferably determined with the condition given by the formula (1), as shown in FIG. 38.

Here, the length of the channel section of the TFT section 22 of the liquid crystal panel is set as W=25 μm, L=5 μm, for example. The radius r in this length is 12.7 μm and the dropping position error Δ2 of the inkjet is 15 μm. Further, the error Δ1 due to unpredictability of the liquid amount and the outline border is 5 μm.

Accordingly, in this case, the semiconductor layer 6 after processing at least requires an area created by a circle with a radius 12.7+5+15=32.7 μm.

Further, when the end portion 66a of the TFT section gate electrode 66 extends straight upward as shown in FIG. 37, the position of the end portion 66a is preferably determined by setting the distance L2>5+2×15=35 μm from the end portions of the source and drain electrodes 17 and 18. Further, the end portion 66a is preferably provided with the distance given by L3>12.7+5+2×15=47.7 μm from the center f of the channel section. Note that, this example applies the condition of w/2=12.5 μm≈r=12.7 μm.

The TFT array substrate according to the Third and Fourth Embodiments is manufactured by performing the following manufacturing step in addition to the manufacturing steps shown in the First and Second Embodiments.

Specifically, in the step for forming the gate electrode, which is described in the foregoing First and Second Embodiments, the TFT section gate electrode 66 (a branch electrode from the gate electrode 13) is formed with such an arrangement that the portion (the end portion 66a) protruded from the semiconductor layer 16 is smaller in width than the portion in the area of the semiconductor layer 16. With this arrangement, the TFT array substrate of the Third Embodiment can be created.

Further, in the step for forming the gate electrode, which is described in the foregoing First and Second Embodiments, the TFT section gate electrode 66 (a branch electrode from the gate electrode 13) is formed with such an arrangement that the portion (the end portion 66a) protruded from the semiconductor layer 16 is formed along one of the source electrode 17 or the drain electrode 18. With this arrangement, the TFT array substrate of the Third Embodiment can be created.

Further, in the step for forming the gate electrode, which is described in the foregoing First and Second Embodiments, the TFT section gate electrode 66 (a branch electrode from the gate electrode 13) is formed with the condition given by the following formula (1),
L3>r+Δ1+2Δ2 (1)

where r denotes the distance from the center of the channel section to the outermost end of the channel section, Δ1 denotes the first error taking account of variation of amount of the droplet for constituting the semiconductor layer 16 and variation of the spread of the droplet, Δ2 denotes the second error considering the error caused by dropping of the droplet off the target position, and L3 denotes the distance from the center of the channel section to the open end of the branch electrode. With this arrangement, the TFT array substrate of the Fourth Embodiment can be created.

Further, in the step for forming the gate electrode, which is described in the foregoing First and Second Embodiments, the TFT section gate electrode 66 (a branch electrode from the gate electrode 13) is formed with the condition given by the following formula (2),
L2>Δ1+2Δ2 (2)

where Δ1 denotes the first error taking account of variation of the amount of the droplet for constituting the semiconductor layer 16 and variation of the spread of the droplet, Δ2 denotes the second error considering the error caused by dropping of the droplet off the target position, and L2 denotes the distance from the end portions (the end portions near the end portion 66a of the TFT section gate electrode 66) of the source and drain electrodes of the TFT section 22 to the open end portion of the TFT section gate electrode 66. With this arrangement, the TFT array substrate of the Fourth Embodiment can be created.

Further, in the step for dropping a droplet of a resist material on the semiconductor layer 16 so as to create the resist layer with the form of the dropped droplet, which is described in the foregoing First and Second Embodiments, the resist layer is formed with the condition given by the following formula (3),
R>r+Δ1+Δ2 (3)

where r denotes the distance from the center f of the channel section to the outermost end of the channel section, Δ1 denotes the first error taking account of variation of the amount of the droplet for constituting the semiconductor layer 16 and variation of the spread of the droplet, Δ2 denotes the second error considering the error caused by dropping of the droplet off the target position, and R denotes a radius of the resist layer, which is set according to the distance from the center of the channel section. With this arrangement, the TFT array substrate of the Fourth Embodiment can be created.

### Fifth Embodiment

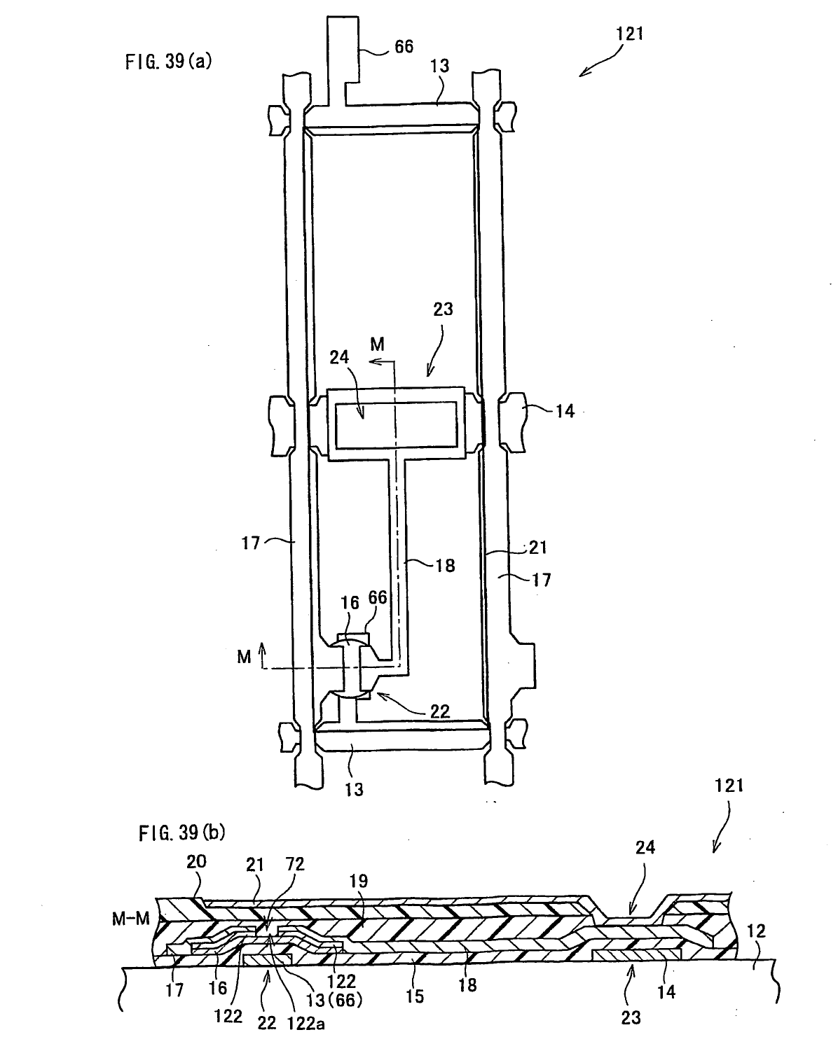

Further embodiment of the present invention is described below with reference to FIGS. 39 through 43.

A liquid crystal display device according to the present embodiment has pixels shown in FIG. 39(a). FIG. 39(a) is a plan view showing the schematic structure of one pixel in a TFT array substrate of the liquid crystal display device. FIG. 39(b) is a cross-sectional view, taken along the line M-M of FIG. 39(a). For members (structures) having substantially same functions as those shown in the drawings pertaining to the first embodiment of the present invention will be given the same reference symbols, and explanation thereof will be omitted here.

As illustrated in FIGS. 39(a) and 39(b), a TFT array substrate 121 includes a glass substrate 12 whereon gate electrodes 13 and source electrodes 17 are arranged in a matrix manner, and the storage capacitor electrodes 14 are formed between adjacent gate electrodes 13.

On a gate electrode 13, a semiconductor layer 16 including an a-Si layer is formed in a substantially circular shape via the gate insulating layer 15, and on this semiconductor layer 16, a conductor layer 122, a source electrode 17 and a drain electrode 18 are formed.

As illustrated in FIG. 39(b), the conductor layer 122 is formed between the semiconductor layer 16 and the source electrode 17 or the drain electrode 18 of the TFT section 22. The conductor layer 122 has a portion formed in a droplet shape where the conductor layer 122 and the semiconductor layer 16 have substantially the same shape.

In the present embodiment, the semiconductor layer 16 is formed through the steps of depositing and processing a film by the CVD as in the first embodiment. The conductor layer 122 is formed by dropping droplets of a conductor material (a material containing metal, for example). As will be explained later, the semiconductor layer 16 is formed in a shape reflecting the shape of the droplet formed in the process of forming the conductor layer 122, i.e., the shape of a conductor forming layer 123. Thus, the portion having the droplet of the conductor layer 122 has substantially the same shape as the semiconductor layer 16. The process of forming the conductor layer 122 will be explained in details later in the explanations of the manufacturing process.

In the present embodiment, the pattern forming equipment, which discharges or drops a material of a layer to be formed, for example, by the inkjet method, is adopted for manufacturing the TFT array substrate 121 as in the first embodiment. Specifically, for example, the pattern forming equipment of FIG. 2 adopted in the first embodiment may be adopted.

The following will explain a manufacturing method of the TFT array substrate 121. Here, explanations will be given in the case of manufacturing the TFT array substrate 121 adopting the pattern forming equipment of FIG. 2 of the first embodiment. Thus, the manufacturing steps of the manufacturing method of the present embodiment are similar to the manufacturing steps shown in FIG. 3 as explained in the first embodiment.

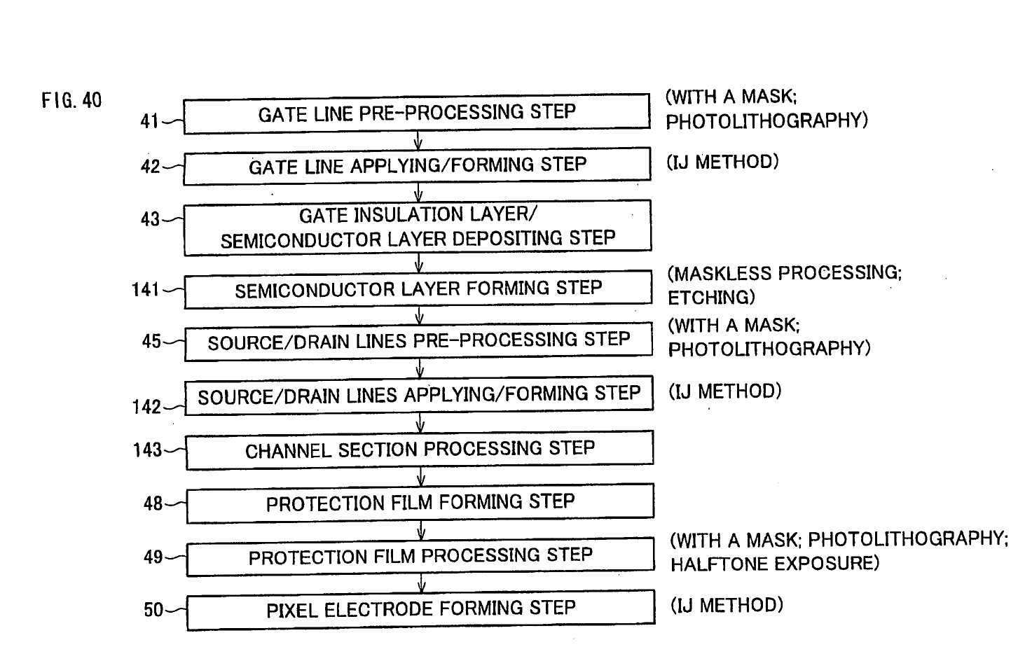

Specifically, as shown in FIG. 40, the manufacturing method of the TFT array substrate 121 includes: a gate line pre-processing step 41, a gate line applying/forming step 42, a gate insulation layer/semiconductor layer depositing step 43, a semiconductor layer forming step 141, a source/drain lines pre-processing step 45, a source/drain lines applying/forming step 142, a channel section processing step 143, a passivation film forming step 48, a passivation film processing step 49, and a pixel electrode forming step 50. In the above steps, the steps other than the semiconductor layer forming step 141, the source/drain lines applying/forming step 142, and the channel section processing step 143 are substantially the same as the corresponding steps in the first embodiment, and explanations thereof shall be omitted here.

[Semiconductor Layer Forming Step 141]

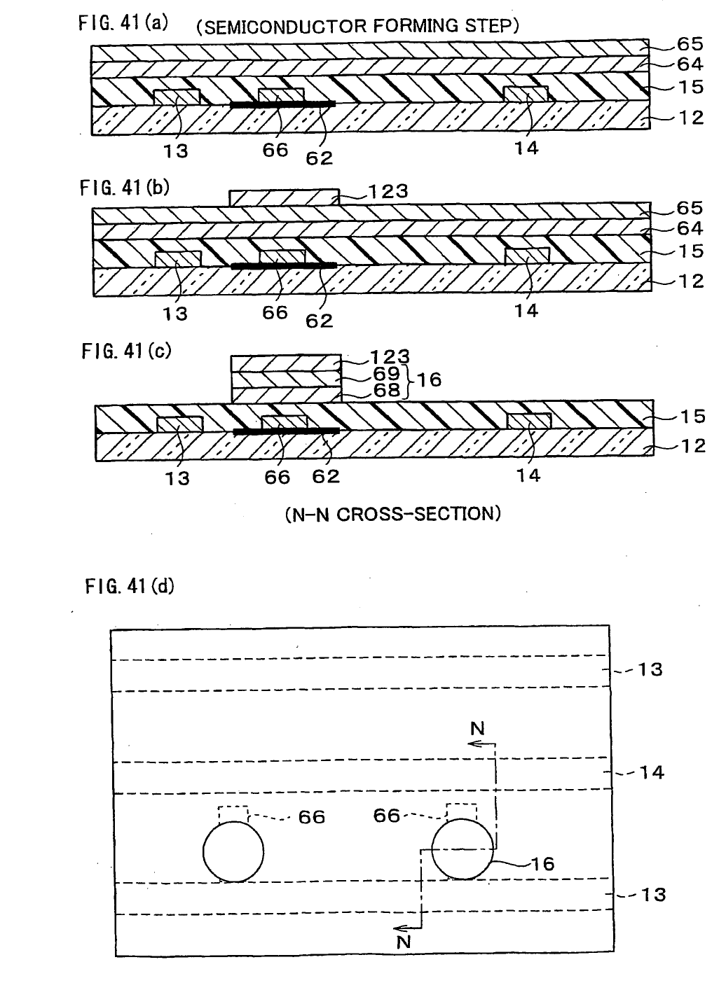

The semiconductor layer forming step 141 is explained below with reference to FIG. 41(a) to FIG. 41(d). FIG. 41(d) is a plan view showing the glass substrate 12 after the semiconductor layer forming step 141. FIGS. 41(a) and 41(b) are cross-sectional views corresponding to a portion taken along the line N-N of FIG. 41(d), and FIG. 41(c) is a cross-sectional view, taken along the line N-N of FIG. 41(d).

FIGS. 41(a) through 41(c) are cross-sectional views respectively show the state directly before starting the semiconductor layer forming step, the state in the semiconductor layer forming step and the state after the semiconductor layer forming step.

FIG. 41(a) is a cross-sectional view showing the state of the glass substrate 12 where the gate insulation layer/semiconductor layer depositing step 43 of FIG. 40 is completed.

In this step, as shown in FIG. 41(b), droplets of a conductor material is dropped from a pattern forming equipment onto the n+ film forming layer 65 in a portion right above a TFT section gate electrode (branch electrode) 66, which is branched out from the main line of the gate electrode 13. The conductor material thus applied by dropping is then baked at 250° C. The resulting conductor forming layer 123 is used as a pattern for processing the n+ film-forming layer 65 and the a-Si film forming layer 64. In this embodiment, the conductor forming layer 123 is formed by a single droplet. The discharging amount of the conductor material is set to, for example, a 10 pl droplet. As a result, a circular pattern with a diameter=30 μm is formed on a predetermined position above the TFT section gate electrode 66.

In this embodiment, in consideration of the temperature at which the a-Si is formed at around 300° C., the baking temperature is set to 250° C. to be lower than 300° C.

In the present embodiment, for the conductor forming layer 123, Mo is adopted. However, the material for the conductor forming layer is not limited to Mo, and, other than Mo, for example, W, Ag, Cr, Ta, Ti or an alloy material including any of the above elements as a main element, a metal material containing any of the above elements as a main element and a non-metal element such as N, O, C, etc., or a metal oxide such as ITO (Indium Tin Oxide), SnO (Tin Oxide), etc., may be adopted.

For the conductor material for use in forming the conductor forming layer 123, a material prepared by dispersing in an organic solvent, Mo fine particles coated with an organic film is adopted. However, a material in a form of a paste, or a material including a metal material as a metal compound dissolved in an organic solvent may be adopted. Furthermore, by controlling dissociation temperatures of the surface coating layer for protecting the fine particles and the organic material in the solvent according to the required baking temperature, the desired resistance and the surface condition can be obtained. Incidentally, the dissociation temperatures denote temperatures at which the surface coating layer and the solvent evaporate.

For the selection of the material which constitutes the conductor forming layer 123, it is necessary to consider such features as being tolerable in the following dry etching process, and the selectivity in etching using a pattern of the source electrode and a drain electrode in the channel section processing step 143. Further, such feature as being not diffusible to the semiconductor layer 16 for avoiding adverse effects on the TFT characteristics later is essential for the material of the conductor forming layer 123.

Next, as shown in FIG. 41(c), the n+ film forming layer 65 and the a-Si film forming layer 64 are subjected to dry etching using a gas (such as SF₆+HCl) so as to form an n+ layer 69 and an a-Si layer 68.

As described, in the semiconductor layer forming step 141, the pattern of the conductor forming layer 123 discharged from the pattern forming equipment directly reflects the shape of the semiconductor layer 16 which is made up of the n+ layer 69 and the a-Si layer 68. Namely, the semiconductor layer 16 is formed in a circular pattern or in a substantially circular pattern made up of a curved line, according to the shape of the material of the conductor forming layer 123 dropped on the glass substrate 12 from an inkjet head 33 (FIG. 2).

Though the conductor forming layer 123 of the present embodiment is formed by a single droplet from the inkjet head 33, the conductor forming layer 123 may be formed by plural droplets. However, it should be noted that, when forming the conductor forming layer 123 by discharging a plurality of extremely small droplets with high precision, a long time is required for forming a semiconductor layer 16, and the life of the inkjet head 33 is shortened as more dot number is required. Therefore, in the case of forming the conductor forming layer 123 by dropping a plurality of droplets, it is desirable to set a size of layer (film) in consideration of the manufacturing time, the life of the inkjet head, etc.

Further, another noticeable characteristic of the semiconductor layer forming step 141 lies in that a special treatment is not required for the surface which receives droplets discharged from the inkjet head 33 as in the first embodiment.

In the conventional method, a mask, or photolithography process is required for the patterning of the semiconductor layer. In contrast, according to the semiconductor layer forming step 141 of the present invention, the mask pattern (corresponding to the resist layer 67 in FIG. 5(b)) is directly drawn with a droplet dropped from the inkjet head 33, and the mask and the photolithography process can be omitted. As a result, a significant cost reduction can be realized.

[Source/Drain Lines Applying/Forming Step 142]

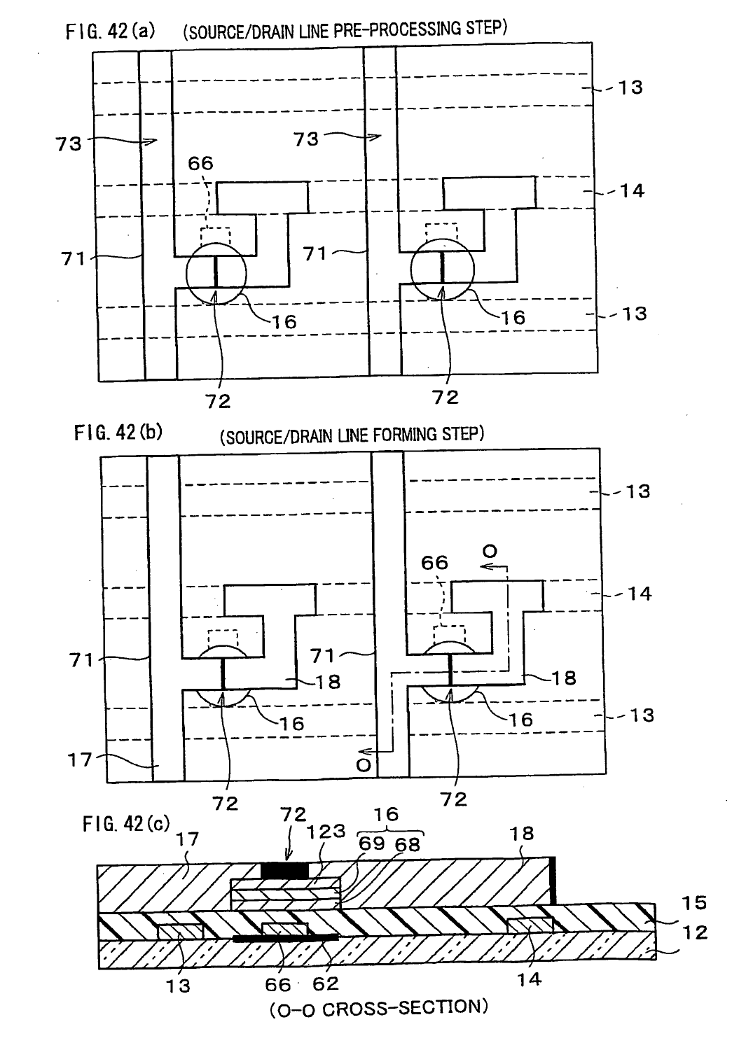

FIG. 42(a) is a plan view showing the state of the glass substrate 12 having gone through the source/drain line pre-processing step 45.

This source/drain lines applying/forming step 142 is shown in FIG. 42(b) and FIG. 42(c). FIG. 42(b) is a plan view showing the source and drain electrodes 17 and 18 which are formed along the wiring guide 71, and FIG. 42(c) is a cross-sectional view, taken along the line O-O of FIG. 42(b).

The Source/drain lines applying/forming step 142 of the present embodiment is performed in the same manner as the first embodiment. However, for the selection of the wiring material, durability according to the etching process conditions for the conductor forming film 123 to be described later need to be considered. In the present embodiment, for the wiring material, a material prepared by dispersing Al, fine particles coated with an organic film in an organic solvent is adopted. However, the wiring material of the present invention is not limited to this material. Other than Al, an Al alloy such as Al—Ti, Al—Nd, etc., Ag, or such Ag alloy as Ag—Pd, Ag—Cu, etc., ITO (Indium Tin Oxide), Cu, Cu—Ni, etc. These materials may be individually adopted, or in a form of particles of an alloy material, or in a form of a paste dissolved in an organic solvent.

In this embodiment, in consideration of the temperature at which the a-Si is formed, i.e., at around 300° C., the baking temperature is set to 200° C. to be lower than 300° C. as in the first embodiment. According to the structure of the present embodiment, the conductor forming layer 123 to be formed into the conductor layer 122 is made of Mo. Therefore, Al which constitutes the source electrode 17 or the drain electrode 18 can be prevented from being diffused into the semiconductor layer. Therefore, even after having gone through the baking step, diffusion into the semiconductor layer made of Al can be suppressed to be small, without hardly affecting the characteristics of the TFT in practice.

[Channel Section Processing Step 143]

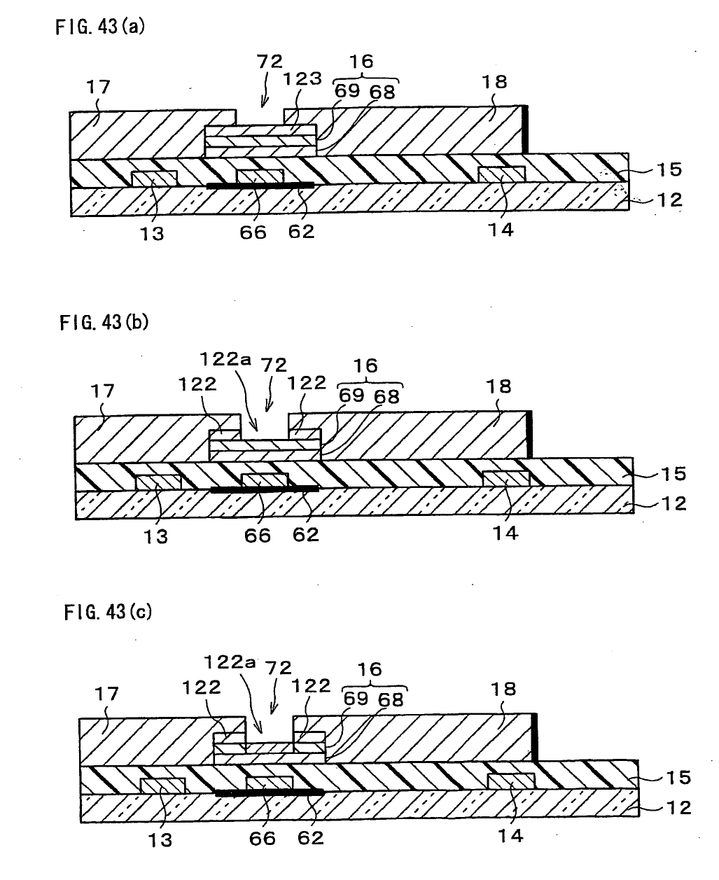

This step is carried out for processing the TFT channel section 72, as shown in FIGS. 43(a) through 43(c). FIGS. 43(a) through 43(c) are cross-sectional views corresponding to a portion taken along the line O-O of FIG. 42(b).

As illustrated in FIG. 43(a), the wiring guide 71 of the channel section 72 is removed by an organic solvent or by ashing.

Next, as shown in FIG. 43(b), a part of the conductor forming layer 123 is selectively removed using the source electrode 17 and the drain electrode 18 as a mask, thereby obtaining a conductor layer 122. In this step, a wet-etching method is adopted using nitric acid with weight percent of 25%. Here, the portion from which the conductor forming layer 123 is removed is formed in an opening section 122a of the conductor layer 122. With this opening section 122a, the semiconductor layer 16 is exposed from the channel section 72. Namely, the opening section 122a is formed in such a manner that the source electrode 17 and the drain electrode 18 are electrically separated in the channel section 72 of the TFT section 22.

In the present embodiment, Al is adopted for the material of the source electrode 17 and the drain electrode 18, and under the foregoing etching conditions, no damage is observed. It is therefore possible to selectively remove only the part of the conductor forming layer 123. It should be noted here, however, that the etching method, and conditions of the conductor forming layer 123 are not limited to the above. The conductions which permit a selective etching of the conductor forming layer 123 may be set in consideration of a material of the conductor forming layer 123, and materials of the source electrode 17, the drain electrode 18, and the gate insulation layer 15. Similarly, although the wet etching method is adopted in the present embodiment, the dry etching method may be adopted under appropriate conditions.

Next, as shown in FIG. 43(c), the n+ layer 69 around the opening section 122a is subjected to oxidation treatment by ashing or by using a laser so as to be a nonconductor.

In the present embodiment, Mo is adopted for the conductor layer 122 as for the conductor forming layer 123. This conductor layer 122 is formed between the source electrode 17 or the drain electrode 18 and the semiconductor layer 16. Therefore, the semiconductor layer 122 serves as an anti-diffusion layer for preventing Al of the materials which constitute the source electrode 17 or the drain electrode 18 from being diffused into the semiconductor layer 16.

Therefore, according to the present embodiment, after having gone through the substrate heating process to be carried out following the channel section processing step 143, Al can be prevented from being diffused into the semiconductor layer 16 with almost no substantial effects on the characteristics of the TFT. The substrate heating step specifically denotes, for example, the step of forming SiO₂ film, forming the photosensitive acrylic acid layer 20 in the protective film forming step 48, the step of baking the ITO fine particle material in the pixel electrode forming step 50.

As explained in the source/drain lines applying/forming step 142, by adopting, for example, Mo for the material of the conductor layer 122, which offers the effect of preventing Al from being diffused into the semiconductor layer 16, the same effect can be appreciated for the conductor forming layer 123 to be formed into the conductor layer 122. Therefore, in the step of baking the substrate at 200° C. added to the source/drain applying/forming step 142, Al can be prevented from being diffused into the semiconductor layer 16, without hardly affecting the characteristics of TFTs in practice.

The material for the source electrode 17 and the drain electrode 18 is not limited to Al, and, for example, a metal material including Al as a main element, for example, an Al alloy may be adopted. In this case, the semiconductor layer 122 made of Mo serves to prevent Al of the Al alloy and/or an element other than Al in the alloy from being diffused into the semiconductor layer 16.

In the case of adopting a material like Al, which is liable to be diffused, for the source electrode 17 and the drain electrode, the productivity would be significantly reduced by the conventional method of separately forming the anti-diffusion layer after forming the semiconductor layer 16, such as the method of forming the source electrode 17 or the drain electrode 18 of a double layer structure of an anti-diffusion layer and a low electric resistance layer on the side of the glass substrate 12.

In contrast, according to the present embodiment, by making the semiconductor layer 122 or the conductor forming layer function as an anti-diffusion layer, the process of separately forming the anti-diffusion layer can be omitted, thereby achieving a significant improvement in productivity.

The effect as achieved from the structure of the present embodiment is appreciated particularly when adopting the inkjet method or other application method for the source electrode 17 and the drain electrode 18. When adopting the application method, the material applied for the first layer needs to be fixed completely before applying the material for the second layer. For this reason, the heating step needs to be performed after applying the material for the first layer before applying the material for the second layer. In this case, such complicated process as transporting the substrate once processed with the application device to the baking equipment, and then carrying the substrate again to the application device is needed, which significantly lowers the productivity. In contrast, according to the method of the present embodiment, the source electrode 17 and the drain electrode 18 can be formed by a single application, and thus such problems associated with the conventional method that elements in the material or substances of the source electrode 17 or the drain electrode 18 are diffused into the semiconductor layer 16 which leads to lower productivity can be eliminated.

According to the structure of the present embodiment, it is possible to make the conductor forming layer 123 to be formed into the conductor layer 122 function as a pattern mask for use in forming the semiconductor layer 16 and as an anti-diffusion layer for preventing the diffusion into the semiconductor layer 16. Further, it is possible to make the conductor layer 122 itself function as an anti-diffusion layer.

Therefore, it is possible to adopt a metal material which is liable to be diffused into the semiconductor layer 16 for the source electrode 17 and the drain electrode 18 without a problem of a reduction in productivity.

As described, according to the manufacturing method of the TFT array substrate 121 of the present embodiment, the required number of masks can be reduced as compared to the conventional manufacturing method which does not adopt the pattern forming equipment by the inkjet method, from five to three, thus the manufacturing method of the present embodiment significantly reduced the required number of photolithography processes and the vacuum deposition devices. On this account, equipment outlay can also be greatly reduced. Furthermore, according to the manufacturing method of the present embodiment, a material, which is liable to be diffused into the semiconductor layer 16, can be adopted for the source electrode 17 and the drain electrode 18 without a problem of a reduction in productivity.

Here, the features explained in the fifth embodiment, such as the TFT array substrate shown in FIG. 39 or the manufacturing method shown in FIG. 40 can be combined with the features explained in the first through fourth embodiments provided that no contradiction arises.

For example, the TFT array substrate of the fifth embodiment may be arranged such that the TFT section gate electrode 66 of the thin film transistor section 22 is a branch electrode branched out from the main line of the gate electrode 13, and the open end of this branch electrode is protruded from the area of the semiconductor layer 16.

It may be arranged such that a part of the branch electrode protruded from the area of the semiconductor layer has a smaller width than a part of the branch electrode within the area of the semiconductor layer.

It may be arranged such that the source electrode 17 and the drain electrode 18 are formed on the semiconductor layer 16, and the channel section 72 is formed between the source electrode 17 and the drain electrode 18, and the part of the branch electrode protruded from the area of the semiconductor layer 16 is formed in a vicinity of either the source electrode 17 or the drain electrode 18.

It may be arranged such that on the semiconductor layer 16, the source electrode 17 and the drain electrode 18 are formed, and the channel section 72 is formed between the source electrode 17 and the drain electrode 18, and the part of the branch electrode protruded from the semiconductor layer 72 is formed with the condition given by the following formula (1),
L3>r+Δ1+2Δ2 (1)

where r denotes a distance from the center of the channel section 72 to the outermost end of the channel section 72, Δ1 denotes the first error in consideration of variations in amount of a droplet to be formed into the semiconductor layer 16 and variations in spread of the droplet, Δ2 denotes the second error in consideration of the displacement of a dropped position of the droplet from the target position, and L3 denotes a distance from the center of the channel section to the open end of the branch electrode.

It may be arranged such that on the semiconductor layer 16, the source electrode 17 and the drain electrode 18 are formed, and the channel section 72 is formed between the source electrode 17 and the drain electrode 18, and the portion of the branch electrode protruded from the semiconductor layer 16 is formed with the condition given by the following formula (2),
L2>Δ1+2Δ2 (2)

where Δ1 denotes the first error in consideration of variations in amount of a droplet to be formed into the semiconductor layer 16 and variations in spread of the droplet, Δ2 denotes the second error in consideration of the displacement of a dropped position of the droplet from the target position, and L2 denotes a distance from the end portions on the open end side of the branch electrode of the source and drain electrodes to the open end of the branch electrode.

It may be arranged such that the source electrode 17 and the drain electrode 18 are formed on the semiconductor layer 16, and the channel section 72 is formed between these electrodes, further the end on the channel section 72 in the source electrode 17 and the drain electrode 18 are formed to the entire width in the region where the semiconductor layer 16 is formed.

It may be further arranged such that a light blocking film in a droplet form is formed in a position corresponding to the position where the semiconductor layer 16 is formed, either in the upper layer or the lower layer of the semiconductor layer 16.

It may be arranged such that on the semiconductor layer 16, the source electrode 17 and the drain electrode 18 are formed, and the channel section 72 is formed between the source electrode 17 and the drain electrode 18, and the semiconductor layer 16 is formed with the condition given by the following formula (3),
R>r+Δ1+Δ2 (3)

where r denotes a distance from the center of the channel section to the outermost end of the channel section, Δ1 denotes the first error in consideration of variations in amount of a droplet to be formed into the semiconductor layer 16 and variations in spread of the droplet, Δ2 denotes the second error in consideration of the displacement of a dropped position of the droplet from the target position, and R denotes a radius of the semiconductor layer, which is set according to the distance from the center of the channel section 72.

The manufacturing method of the TFT array substrate of the fifth embodiment may be arranged such that the TFT section gate electrode 66 of the thin film transistor section 22 is a branch electrode branched out from the main line of the gate electrode 13, and the open end of this branch electrode is protruded from the area of the semiconductor layer 16.

Further, it may be arranged such that the length of the branch electrode is set so that the open end thereof can be protruded from the semiconductor layer 16 in consideration of a dropping precision.

It may be arranged such that the part of the branch electrode protruded from the area of the semiconductor layer has a smaller width than the part of the branch electrode within the area of the semiconductor layer 16.

It may be arranged such that the source electrode and the drain electrode are formed on the semiconductor layer 16, and the channel section 72 is formed between the source electrode 17 and the drain electrode 18, and the portion of the branch electrode protruded from the area of the semiconductor layer 16 is formed in a vicinity of either the source electrode or the drain electrode.

In the manufacturing process of the gate electrode 13, the portion of the branch electrode protruded from area of the semiconductor layer 16 may be formed with the condition given by the following formula (1),
L3>r+Δ1+2Δ2 (1)

where r denotes a distance from the center of the channel section 72 to the outermost end of the channel section 72, Δ1 denotes the first error in consideration of variations in amount of a droplet to be formed into the semiconductor layer 16 and variations in spread of the droplet, Δ2 denotes the second error in consideration of the displacement of a dropped position of the droplet from the target position, and L3 denotes a distance from the center of the channel section to the open end of the branch electrode.

In the manufacturing process of the gate electrode 13, the portion of the branch electrode protruded from the semiconductor layer 72 may be formed with the condition given by the following formula (2),
L2>Δ1+2Δ2 (2)

where Δ1 denotes the first error in consideration of variations in amount of a droplet to be formed into the semiconductor layer 16 and variations in spread of the droplet, Δ2 denotes the second error in consideration of the displacement of a dropped position of the droplet from the target position, and L2 denotes a distance from the end portions on the open end side of the branch electrode of the source and drain electrodes to the open end of the branch electrode.

Further, the first and the second areas may be provided by forming a convex guide which prevents flow of the droplet.

Further, the first and the second areas may be provided by forming a lyophilic area and a lyophobic area respectively having a lyophilic characteristic and a lyophobic characteristic with respect to the droplets.

The structure of the foregoing fifth embodiment may be combined with the structure of each of the first through fourth embodiments, and such combination will offer the same function and effect as achieved the structure of each of the first through fourth embodiments.

The TFT array substrate of the fifth embodiment is suitably applied to a liquid crystal display device; however, the TFT array substrate may be applied to other display device such as a display device for an organic EL panel or an inorganic EL panel, etc., or a two-dimensional image input device represented by a fingerprint sensor, an x-ray imaging device, etc., or various electronic devices adopting the TFT array substrate. The same can be said for the TFT array substrate adopted in each of the first through fourth embodiments, and the TFT array substrate is applicable to not only the liquid crystal display device, but also to other devices as listed above.

Similarly, the manufacturing method of the TFT array substrate of the fifth embodiment is suitably applied to the manufacturing method of the liquid crystal display device. However, the manufacturing method of the fifth embodiment is also applicable to the manufacturing method of other display device such as a display device for an organic EL panel or an inorganic EL panel, etc., or a two-dimensional image input device represented by a fingerprint sensor, an x-ray imaging device, etc., or various electronic devices adopting the TFT array substrate. The same can be said for the manufacturing method of the TFT array substrate adopted in each of the first through fourth embodiments, and the manufacturing method of the TFT array substrate is applicable to not only the manufacturing method of liquid crystal display device, but also to the manufacturing method of other devices as listed above.

As described, the TFT array substrate according to the present invention includes a semiconductor layer having a shape formed by dropping a droplet.

On this account, the manufacturing of the TFT array substrate can be performed without a mask for forming a semiconductor layer. As a result, the number of masks is reduced, thus reducing manufacturing processes. Further, the manufacturing requires less photolithography processes using a mask, thus reducing equipment outlay for the photolithography and amount of waste material. This allows reduction of time and costs of manufacturing.

The TFT array substrate may have such an arrangement that the gate electrode in the thin film transistor section is a branch electrode which is branched out of a main line of the gate electrode, and the branch electrode has an open end protruded from an area for the semiconductor layer.

With the foregoing arrangement, since the open-end of the branch electrode of the thin film transistor section is protruded from the area for the semiconductor layer, a leak current between the source and drain electrodes can be appropriately suppressed by the electrical field from the branch electrode.

The TFT array substrate according to the present invention may have such an arrangement that the branch electrode is arranged so that a portion protruded from the area for the semiconductor layer is smaller in width than a portion confined within the area for the semiconductor layer.

With the foregoing arrangement, the open-end of the branch electrode occupies less area of the pixel section, thus suppressing decrease of aperture ratio.

The TFT array substrate according to the present invention may have such an arrangement that the thin film transistor section further includes a source electrode and a drain electrode on the semiconductor layer, and a channel section is formed between the source and drain electrodes, and the portion of the branch electrode protruded from the area for the semiconductor layer is formed in contact with one of the source and drain electrodes.

With the foregoing arrangement, since the portion of the branch electrode protruded from the area for the semiconductor layer is formed in contact with one of the source and drain electrodes, the open-end of the branch electrode may be extended to be out of the semiconductor layer, without decreasing the aperture ratio of the pixel section of the TFT array substrate.

By adopting this arrangement, it is possible to securely provide the branch electrode with an open-end protruded from the semiconductor layer, thus securely suppressing the leak current between the source and drain electrodes.

Further, the following formula may be referred to form the portion protruded from the semiconductor layer.

Namely, the TFT array substrate according to the present invention may have such an arrangement that the thin film transistor section further includes a source electrode and a drain electrode on the semiconductor layer, and a channel section is formed between the source and drain electrodes, and the portion of the branch electrode protruded from the area for the semiconductor layer is formed according to the following formula (1),
L3>r+Δ1+2Δ2 (1)

where r denotes a distance from a center of the channel section to an outermost end of the channel section, Δ1 denotes a first error taking account of variation of dropping amount of the droplet for forming the semiconductor layer and variation of spread of the droplet after dropping, Δ2 denotes a second error taking account of dropping off a target position, and L3 denotes a distance from the center of the channel section to the open end of the branch electrode.

Further, the TFT array substrate according to the present invention may have such an arrangement that the thin film transistor section further includes a source electrode and a drain electrode on the semiconductor layer, and a channel section is formed between the source and drain electrodes, and the portion of the branch electrode protruded from the area for the semiconductor layer is formed according to the following formula (2),
L2>Δ1+2Δ2 (2)

where Δ1 denotes a first error taking account of variation of dropping amount of the droplet for forming the semiconductor layer and variation of spread of the droplet after dropping, Δ2 denotes a second error taking account of dropping off a target position, and L2 denotes a distance from (1) an end of each of the source and drain electrodes, closer to the open end of the branch electrode, to (2) the open end of the branch electrode.

The foregoing TFT array substrate may have such an arrangement that the thin film transistor section further includes a source electrode and a drain electrode on the semiconductor layer, and a channel section is formed between the source and drain electrodes, and the source and drain electrodes each have an end that is positioned closer to the channel section, and confined over an entire width within the area for the semiconductor layer.

With the foregoing arrangement, the source electrode of each pixel can be supplied with a sufficient ON current, thus preventing nonuniformity of charging condition of the pixel, which causes unevenness of the image.

The TFT array substrate according to the present invention may have such an arrangement that the thin film transistor section further includes a light-blocking film on either of an upper layer or an lower layer of the semiconductor layer, the light-blocking film having a shape formed by dropping a droplet, and being formed on a portion corresponding to the position of the semiconductor layer.

With the foregoing arrangement, when the light-blocking film is required, it can be created easily by dropping a droplet(s) of a light-blocking film material by using an inkjet method or the like. Accordingly, as with the forming of the semiconductor layer, the light-blocking film can be formed without a mask. On this account, it is not necessary to use extra number of masks or larger amount of material in the manufacturing of the TFT array substrate, thus reducing manufacturing steps and costs.

The TFT array substrate according to the present invention may have such an arrangement that the thin film transistor section further includes a source electrode and a drain electrode on the semiconductor layer, and a channel section is formed between the source and drain electrodes, and the semiconductor layer is formed according to the following formula (3),
R>r+Δ1+Δ2 (3)

where r denotes a distance from a center of the channel section to an outermost end of the channel section, Δ1 denotes a first error taking account of variation of dropping amount of the droplet for forming the semiconductor layer and variation of spread of the droplet after dropping, Δ2 denotes a second error taking account of dropping off a target position, and R denotes a radius of the semiconductor layer, which extends from the center of the channel section.

With the foregoing arrangement, the semiconductor layer can be securely provided in the channel section of the thin film transistor section, thus ensuring desirable level of the characteristics of the thin film transistor section.

The liquid crystal display device of the present invention includes the foregoing TFT array substrate. Therefore, the manufacturing of the liquid crystal display requires less number of masks, thus reducing time and costs of manufacturing.

A manufacturing method of the TFT array substrate according to the present invention includes the steps of: (a) forming a gate electrode on a substrate; (b) forming a gate insulation layer on the gate electrode; (c) depositing a semiconductor film on the gate insulation layer; (d) forming a resist layer having a shape of a droplet by dropping a droplet of a resist material on the semiconductor film; and (e) removing the resist layer, after processing the semiconductor film corresponding to the shape of the resist layer so as to create a semiconductor layer of a thin film transistor section.

In this manner, a resist layer is formed on a deposited semiconductor film by dropping a droplet of a resist material, and the semiconductor layer is formed by using this resist layer having the shape of the droplet (normally a circular shape) as a mask.

Accordingly, the forming of the semiconductor layer does not require a mask, and therefore, the total required number of masks is reduced, thus reducing manufacturing processes.

Further, since the manufacturing requires less photolithography processes using a mask, it is possible to reduce equipment outlay for the photolithography and amount of waste material. This allows reduction of time and costs of manufacturing.

A manufacturing method of the TFT array substrate according to the present invention includes the steps of: (a) forming a gate electrode on a substrate; (b) forming a gate insulation layer on the gate electrode; and (c) forming a semiconductor layer having a shape of a droplet as a semiconductor layer of a thin film transistor section, by dropping a droplet of a semiconductor material on the gate insulation layer on the branch electrode.

In this manner, the semiconductor layer is formed in a shape of a droplet (normally a circular shape) by only dropping a droplet of a semiconductor material on the gate insulation layer of the branch electrode.

Accordingly, the forming of the semiconductor layer does not require a mask, and therefore, the total required number of masks is reduced, thus reducing manufacturing processes.

Further, since the manufacturing requires less photolithography processes using a mask, it is possible to reduce equipment outlay for the photolithography and amount of waste material. This allows reduction of time and costs of manufacturing.

The foregoing manufacturing method of the TFT array substrate according to the present invention may be arranged so that: in the step (a), the gate electrode is formed so that the gate electrode includes a main line and a branch electrode branched out of the main line, the branch electrode having an open end protruded from an area for the semiconductor layer.

With the foregoing arrangement, since the branch electrode of the gate electrode of the thin film transistor section has an open-end protruded from the area for the semiconductor layer, a leak current between the source and drain electrodes can be appropriately suppressed by the electrical field from the branch electrode.

The foregoing manufacturing method of the TFT array substrate may be arranged so that: the branch electrode is specified by length according to dropping accuracy of the droplet so that the open end is protruded from the area for the semiconductor layer.

In this manner, the droplet of a resist material or a semiconductor material is dropped in a position for allowing the open-end of the branch electrode to be protruded from the area for the completed semiconductor. Thus, the leak current between the source and drain electrodes can be appropriately suppressed.

The manufacturing method of the TFT array substrate according to the present invention may be arranged so that: the branch electrode is formed so that a portion protruded from the area for the semiconductor layer is smaller in width than a portion confined within the area for the semiconductor layer.

With the foregoing arrangement, the open-end of the branch electrode occupies less area of the pixel section, thus suppressing decrease of aperture ratio.

The manufacturing method of the TFT array substrate according to the present invention may be arranged so that: the portion of the branch electrode protruded from the area for the semiconductor layer is formed in contact with one of source and drain electrodes of the thin film transistor section.

With the foregoing arrangement, since the portion of the branch electrode protruded from the area for the semiconductor layer is formed in contact with one of the source and drain electrodes, the open-end of the branch electrode may be extended to be out of the semiconductor layer, without decreasing the aperture ratio of the pixel section of the TFT array substrate.

By adopting this arrangement, it is possible to securely provide the branch electrode with an open-end protruded from the semiconductor layer, thus securely suppressing the leak current between the source and drain electrodes.

The manufacturing method of the TFT array substrate according to the present invention may be arranged so that: in the step (a), the branch electrode is formed so that a portion protruded from the area for the semiconductor layer is formed according to the following formula (1),
L3>r+Δ1+2Δ2 (1)

where r denotes a distance from a center of the channel section to an outermost end of the channel section, Δ1 denotes a first error taking account of variation of dropping amount of the droplet for forming the semiconductor layer and variation of spread of the droplet after dropping, Δ2 denotes a second error taking account of dropping off a target position, and L3 denotes a distance from the center of the channel section to the open end of the branch electrode.

Further, in the step (a), the branch electrode is formed so that a portion protruded from the area for the semiconductor layer is formed according to the following formula (2),
L2>Δ1+2Δ2 (2)

where Δ1 denotes a first error taking account of variation of dropping amount of the droplet for forming the semiconductor layer and variation of spread of the droplet after dropping, Δ2 denotes a second error taking account of dropping off a target position, and L2 denotes a distance from (1) an end of each of the source and drain electrodes, closer to the open end of the branch electrode, to (2) the open end of the branch electrode.

In both of the foregoing arrangements, it is possible to securely provide the branch electrode with an open-end protruded from the semiconductor layer, thus securely suppressing the leak current between the source and drain electrodes.

The manufacturing method of the TFT array substrate according to the present invention may be arranged so that: in the step (d), the resist layer is formed according to the following formula (3),
R>r+Δ1+Δ2 (3)

where r denotes a distance from a center of the channel section to an outermost end of the channel section, Δ1 denotes a first error taking account of variation of dropping amount of the droplet for forming the semiconductor layer and variation of spread of the droplet after dropping, Δ2 denotes a second error taking account of dropping off a target position, and R denotes a radius of the semiconductor layer, which extends from the center of the channel section.

With the foregoing arrangement, the semiconductor layer can be securely provided in the channel section of the thin film transistor section, thus ensuring desirable level of the characteristics of the thin film transistor section.

A manufacturing method of a TFT array substrate according to the present invention includes the steps of: (a) forming a gate electrode on a substrate; (b) forming a gate insulation layer on the gate electrode; (c) forming a semiconductor layer of a thin film transistor section on the gate insulation layer; (d) forming a first area to which a source electrode is formed, and a second area to which at least a pixel electrode is formed, by dropping a droplet of an electrode material on the substrate after subjected to the step (c); and (e) forming a source electrode, a drain electrode, and a pixel electrode in the first and the second areas by dropping droplets of an electrode material on the substrate after subjected to the step (d).

In this manner, the first area to which a source electrode is formed by dropping a droplet of an electrode material, and the second area to which at least a pixel electrode is formed by dropping a droplet of an electrode material are formed in one process for pre-processing of the electrode forming step. Therefore, the manufacturing processes and costs can be reduced compared to the case of separately forming the first and the second areas in different steps.

A manufacturing method of a liquid crystal display device according to the present invention includes one of the foregoing manufacturing methods of a TFT array substrate. Therefore, it is possible to reduce at least manufacturing processes for producing a liquid crystal display device, thus reducing costs.

A TFT array substrate according to the present invention includes: a thin film transistor section in which a gate electrode is formed on a substrate, and a semiconductor layer and a conductor layer are formed on the gate electrode via a gate insulation layer, wherein: the conductor layer is formed in contact with the semiconductor layer and one of source and drain electrodes of the thin film transistor section, and has a portion formed by dropping a droplet, the conductor layer and the semiconductor layer having substantially the same shape in the portion formed by dropping a droplet.

In this arrangement, a conductor forming layer is formed on a deposited semiconductor film by dropping a droplet of a conductive material, and the semiconductor layer is formed by using this conductor forming layer having the shape of the droplet (normally a circular shape) as a mask. This conductor forming layer is not required to be removed unlike the resist layer, and therefore, the removal process can be omitted. In this arrangement, the dropping of the droplet of a conductive material onto the semiconductor layer can be carried out by an inkjet method, for example, or by any methods enabling formation of a droplet having an appropriate size for a semiconductor layer of the thin film transistor section.

With this arrangement of a TFT array substrate, the semiconductor layer can be formed without a mask; and therefore the required number of masks is reduced. Further, the conductor forming layer is not required to be removed unlike the resist layer, and therefore the removal process can be omitted, thus greatly reducing manufacturing processes and equipment outlay. Moreover, the required amount of chemicals, such as a developer or removing agent can also be reduced, as well as amount of waste of the resist material etc. On this account, it is possible to reduce the time and costs of manufacturing.

Further, the conductor layer may be constituted of Mo, W, Ag, Cr, Ta, Ti, a metal material mainly containing one of Mo, W Ag, Cr, Ta, Ti, or an indium tin oxide.

More specifically, with the foregoing arrangement, the conductor layer, provided between the semiconductor layer and the source or drain electrode, operates as a diffusion preventing layer for practically preventing diffusion of a component element(s) constituting the source electrode or the drain electrode. Further, the conductor forming layer, which is a previous state of the conductor layer, also operates as the diffusion preventing layer. By thus practically preventing diffusion, the diffusion amount of the materials to the semiconductor layer is small even after heat treatment, so that there is few practical influence of the diffusion to the characteristic of the TFT.

The foregoing configuration of the present invention can deal with such a circumstance of recent years that a source or drain electrode is often made of Al, Cu or the like, which is likely to diffuse into the semiconductor layer. Therefore, the configuration of the present invention has a wider selection range of materials for constituting a source or drain electrode, while hardly increasing the number of manufacturing processes.

With this arrangement, manufacturing processes can be greatly reduced compared to the conventional method for forming a diffusion preventing layer after the semiconductor layer, for example, a method in which the source and drain electrodes are respectively constituted of a diffusion preventing layer and a low electric resistance layer, in this order from the glass substrate. On this account, productivity of the TFT array substrate can be improved.

Particularly, it is effective in terms of manufacturing that the source and drain electrodes are made of an Al or a metal material mainly containing Al.

As one of their characteristics, an Al or the metal material mainly containing Al are not easily damaged by an oxidative acid, such as a nitric acid. Thus, the conductor forming layer is preferably made of an Ag, Mo, W, or an alloy mainly containing an Ag, Mo, W, which are soluble by an oxidative acid such as a nitric acid. This arrangement is advantageous in manufacturing, since the wet-etching can be carried out only for the conductive forming layer with desirable selectivity by using an oxidative acid, such as a nitric acid.

Further, since the source and drain electrodes made of an Al or the metal material mainly containing Al have a low electric resistance. Therefore the TFT array substrate can be compatible with a recent large-sized TFT array substrate.

Further, the liquid crystal display device according to the present invention includes the foregoing TFT array substrate. Therefore, it is possible to reduce manufacturing processes of a TFT array substrate, thus reducing the time and costs of manufacturing.

A manufacturing method of a TFT array substrate according to the present invention includes the steps of: (a) forming a gate electrode on a substrate; (b) forming a gate insulation layer on the gate electrode; (c) depositing a semiconductor film on the gate insulation layer; (d) forming a conductor forming layer having a shape of a droplet by dropping a droplet of a conductive material on the semiconductor film; and (e) forming a semiconductor layer of a thin film transistor section by processing the semiconductor film corresponding to the shape of the conductor forming layer.

In this arrangement, a conductor forming layer is formed on a deposited semiconductor film by dropping a droplet of a conductive material, and the semiconductor layer is formed by using this conductor forming layer having the shape of the droplet (normally a circular shape) as a mask. This conductor forming layer is not required to be removed unlike the resist layer, and therefore, the removal process can be omitted.

With this arrangement of a TFT array substrate, the semiconductor layer can be formed without a mask; and therefore the required number of masks is reduced, thus reducing manufacturing processes. Further, the manufacturing requires less photolithography processes using a mask, thus reducing equipment outlay for the photolithography, thus greatly reducing manufacturing processes and equipment outlay. Moreover, the required amount of chemicals, such as a developer or removing agent can also be reduced, as well as amount of waste of the resist material etc. On this account, it is possible to reduce the time and costs of manufacturing.

Further, the foregoing manufacturing method of a TFT array substrate may further includes the step of: processing the conductor forming layer so as to form a conductor layer, wherein: the conductor layer is constituted of Mo, W, Ag, Cr, Ta, Ti, a metal material mainly containing one of Mo, W, Ag, Cr, Ta, Ti, or an indium tin oxide.

With this method, the configuration of the present invention has a wider selection range of materials for constituting a source or drain electrode, while hardly increasing the number of manufacturing processes. More specifically, the conductor forming layer as a previous state of the conductor layer operates as a pattern mask for forming the semiconductor layer and also as a diffusion preventing layer for preventing the diffusion into the semiconductor layer.

Furthermore, the conductor layer created from the conductor forming layer also has the diffusion preventing function. Accordingly, selection range of material becomes wider since the source and drain electrodes may be made of an Al or an Cu, which have a low electrical resistance.

The source and drain electrodes are preferably made of an Al or a metal material mainly containing Al.

Here, the conductor forming layer is preferably made of an Ag, Mo, W, or an alloy mainly containing an Ag, Mo, W, which are soluble by an oxidative acid such as a nitric acid.

This arrangement is advantageous in manufacturing, since the wet-etching can be carried out only for the conductive forming layer with desirable selectivity by using an oxidative acid, such as a nitric acid.

On this account, it is possible to, for example, reduce manufacturing processes of a TFT array substrate, thus improving productivity of a TFT array substrate.

The manufacturing method of a liquid crystal display device according to the present invention includes one of the foregoing manufacturing methods of a TFT array substrate. Therefore, it is possible to reduce at least manufacturing processes for producing a liquid crystal display device.

For a fuller understanding of the nature and advantages of the invention, reference should be made to the ensuing detailed description taken in conjunction with the accompanying drawings.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

### INDUSTRIAL APPLICABILITY

The TFT array substrate according to the present invention is manufactured through an inkjet method. The TFT array substrate may be adopted for a field requiring reduction in costs and numbers of manufacturing processes. The TFT array substrate is particularly suitable for a liquid crystal display device; however, it is also compatible with other display devices (such as an organic EL panel) or a imaging device.

1. A TFT array substrate, comprising:
a thin film transistor section in which a gate electrode is formed on a substrate, and a semiconductor layer is formed on the gate electrode via a gate insulation layer,
the processed semiconductor layer having a shape formed by dropping a droplet.

2. The TFT array substrate as set forth in claim 1, wherein:
the gate electrode in the thin film transistor section is a branch electrode which is branched out of a main line of the gate electrode, and the branch electrode has an open end protruded from an area for the semiconductor layer.

3. The TFT array substrate as set forth in claim 2, wherein:
the branch electrode is arranged so that a portion protruded from the area for the semiconductor layer is smaller in width than a portion confined within the area for the semiconductor layer.

4. The TFT array substrate as set forth in claim 2, wherein:
the thin film transistor section further includes a source electrode and a drain electrode on the semiconductor layer, and a channel section is formed between the source and drain electrodes, and the portion of the branch electrode protruded from the area for the semiconductor layer is formed in contact with one of the source and drain electrodes.

5. The TFT array substrate as set forth in claim 2, wherein:
the thin film transistor section further includes a source electrode and a drain electrode on the semiconductor layer, and a channel section is formed between the source and drain electrodes, and the portion of the branch electrode protruded from the area for the semiconductor layer is formed according to the following formula (1),
L3>r+Δ1+2Δ2 (1)
where r denotes a distance from a center of the channel section to an outermost end of the channel section, Δ1 denotes a first error taking account of variation of dropping amount of the droplet for forming the semiconductor layer and variation of spread of the droplet after dropping, Δ2 denotes a second error taking account of dropping off a target position, and L3 denotes a distance from the center of the channel section to the open end of the branch electrode.

6. The TFT array substrate as set forth in claim 2, wherein:
the thin film transistor section further includes a source electrode and a drain electrode on the semiconductor layer, and a channel section is formed between the source and drain electrodes, and the portion of the branch electrode protruded from the area for the semiconductor layer is formed according to the following formula (2),
L2>Δ1+2Δ2 (2)
where Δ1 denotes a first error taking account of variation of dropping amount of the droplet for forming the semiconductor layer and variation of spread of the droplet after dropping, Δ2 denotes a second error taking account of dropping off a target position, and L2 denotes a distance from (1) an end of each of the source and drain electrodes, closer to the open end of the branch electrode, to (2) the open end of the branch electrode.

7. The TFT array substrate as set forth in claim 1, wherein:
the thin film transistor section further includes a source electrode and a drain electrode on the semiconductor layer, and a channel section is formed between the source and drain electrodes, and the source and drain electrodes each have an end that is positioned closer to the channel section, and confined over an entire width within the area for the semiconductor layer.

8. The TFT array substrate as set forth in claim 1, wherein:
the thin film transistor section further includes a light-blocking film on either of an upper layer or an lower layer of the semiconductor layer, the light-blocking film having a shape formed by dropping a droplet, and being formed on a portion corresponding to the position of the semiconductor layer.

9. The TFT array substrate as set forth in claim 1, wherein:
the thin film transistor section further includes a source electrode and a drain electrode on the semiconductor layer, and a channel section is formed between the source and drain electrodes, and the semiconductor layer is formed according to the following formula (3),
R>r+Δ1+Δ2 (3)
where r denotes a distance from a center of the channel section to an outermost end of the channel section, Δ1 denotes a first error taking account of variation of dropping amount of the droplet for forming the semiconductor layer and variation of spread of the droplet after dropping, Δ2 denotes a second error taking account of dropping off a target position, and R denotes a radius of the semiconductor layer, which extends from the center of the channel section.

10. A liquid crystal display device including the TFT array substrate as set forth in claim 1.

11. A manufacturing method of a TFT array substrate, comprising the steps of:
(a) forming a gate electrode on a substrate;
(b) forming a gate insulation layer on the gate electrode;
(c) depositing a semiconductor film on the gate insulation layer;
(d) forming a resist layer having a shape of a droplet by dropping a droplet of a resist material on the semiconductor film; and
(e) removing the resist layer, after processing the semiconductor film corresponding to the shape of the resist layer so as to create a semiconductor layer of a thin film transistor section.

12. The manufacturing method of a TFT array substrate as set forth in claim 11, wherein:
in the step (a), the gate electrode is formed so that the gate electrode includes a main line and a branch electrode branched out of the main line, the branch electrode having an open end protruded from an area for the semiconductor layer.

13. The manufacturing method of a TFT array substrate as set forth in claim 12, wherein:
the branch electrode is specified by length according to dropping accuracy of the droplet so that the open end is protruded from the area for the semiconductor layer.

14. The manufacturing method of a TFT array substrate as set forth in claim 12, wherein:
the branch electrode is formed so that a portion protruded from the area for the semiconductor layer is smaller in width than a portion confined within the area for the semiconductor layer.

15. The manufacturing method of a TFT array substrate as set forth in claim 12, wherein:
the portion of the branch electrode protruded from the area for the semiconductor layer is formed in contact with one of source and drain electrodes of the thin film transistor section.

16. The manufacturing method of a TFT array substrate as set forth in claim 12, wherein:
in the step (a), the branch electrode is formed so that a portion protruded from the area for the semiconductor layer is formed according to the following formula (1),
L3>r+Δ1+2Δ2 (1)
where r denotes a distance from a center of the channel section to an outermost end of the channel section, Δ1 denotes a first error taking account of variation of dropping amount of the droplet for forming the semiconductor layer and variation of spread of the droplet after dropping, Δ2 denotes a second error taking account of dropping off a target position, and L3 denotes a distance from the center of the channel section to the open end of the branch electrode.

17. The manufacturing method of a TFT array substrate as set forth in claim 13, wherein:
in the step (a), the branch electrode is formed so that a portion protruded from the area for the semiconductor layer is formed according to the following formula (2),
L2>Δ1+2Δ2 (2)
where Δ1 denotes a first error taking account of variation of dropping amount of the droplet for forming the semiconductor layer and variation of spread of the droplet after dropping, Δ2 denotes a second error taking account of dropping off a target position, and L2 denotes a distance from (1) an end of each of the source and drain electrodes, closer to the open end of the branch electrode, to (2) the open end of the branch electrode.

18. The manufacturing method of a TFT array substrate as set forth in claim 11, wherein:
in the step (d), the resist layer is formed according to the following formula (3),
R>r+Δ1+Δ2 (3)
where r denotes a distance from a center of the channel section to an outermost end of the channel section, Δ1 denotes a first error taking account of variation of dropping amount of the droplet for forming the semiconductor layer and variation of spread of the droplet after dropping, Δ2 denotes a second error taking account of dropping off a target position, and R denotes a radius of the semiconductor layer, which extends from the center of the channel section.

19. A manufacturing method of a TFT array substrate, comprising the steps of:
(a) forming a gate electrode with a branch electrode on a substrate;
(b) forming a gate insulation layer on the gate electrode; and
(c) forming a semiconductor layer having a shape of a droplet as a semiconductor layer of a thin film transistor section, by dropping a droplet of a semiconductor material on the gate insulation layer on the branch electrode.

20. The manufacturing method of a TFT array substrate as set forth in claim 19, wherein:
in the step (a), the gate electrode is formed so that the gate electrode includes a main line and a branch electrode branched out of the main line, the branch electrode having an open end protruded from an area for the semiconductor layer.

21. The manufacturing method of a TFT array substrate as set forth in claim 19, wherein:
the step (c) includes the sub-steps of:
(i) depositing a semiconductor film on the gate insulation layer;
(ii) forming a resist layer having a shape of a droplet by dropping a droplet of a resist material on the semiconductor film; and
(iii) removing the resist layer, after processing the semiconductor film corresponding to the shape of the resist layer so as to create a semiconductor layer of a thin film transistor section, and
in the step (ii), the resist layer is formed according to the following formula (3),
R>r+Δ1+Δ2 (3)
where r denotes a distance from a center of the channel section to an outermost end of the channel section, Δ1 denotes a first error taking account of variation of dropping amount of the droplet for forming the semiconductor layer and variation of spread of the droplet after dropping, Δ2 denotes a second error taking account of dropping off a target position, and R denotes a radius of the semiconductor layer, which extends from the center of the channel section.

22. A manufacturing method of a TFT array substrate, comprising the steps of:
(a) forming a gate electrode on a substrate;
(b) forming a gate insulation layer on the gate electrode;
(c) forming a semiconductor layer of a thin film transistor section on the gate insulation layer;
(d) forming a first area to which a source electrode is formed, and a second area to which at least a pixel electrode is formed, by dropping a droplet of an electrode material on the substrate after subjected to the step (c); and
(e) forming a source electrode, a drain electrode, and a pixel electrode in the first and the second areas by dropping droplets of an electrode material on the substrate after subjected to the step (d).

23. The manufacturing method of a TFT array substrate as set forth in claim 22, wherein:
the first and the second areas are provided by forming a convex guide which prevents flow of the droplet.

24. The manufacturing method of a TFT array substrate as set forth in claim 22, wherein:
the first and the second areas are provided by forming a lyophilic area and a lyophobic area respectively having a lyophilic characteristic and a lyophobic characteristic with respect to the droplets.

25. A manufacturing method of a liquid crystal display device including the manufacturing method of a TFT substrate as set forth in claim 11.

26. A TFT array substrate, comprising:
a thin film transistor section in which a gate electrode is formed on a substrate, and a semiconductor layer and a conductor layer are formed on the gate electrode via a gate insulation layer,
wherein:
the conductor layer is formed in contact with the semiconductor layer and one of source and drain electrodes of the thin film transistor section, and has a portion formed by dropping a droplet, the conductor layer and the semiconductor layer having substantially the same shape in the portion formed by dropping a droplet.

27. The manufacturing method of a TFT array substrate as set forth in claim 26, wherein:
the conductor layer is constituted of Mo, W, Ag, Cr, Ta, Ti, a metal material mainly containing one of Mo, W, Ag, Cr, Ta, Ti, or an indium tin oxide.

28. The manufacturing method of a TFT array substrate as set forth in claim 27, wherein:
the source and drain electrodes are made of an Al or a metal material mainly containing Al.

29. A liquid crystal display device including the TFT array substrate as set forth in claim 26.

30. A manufacturing method of a TFT array substrate, comprising the steps of:
(a) forming a gate electrode on a substrate;
(b) forming a gate insulation layer on the gate electrode;
(c) depositing a semiconductor film on the gate insulation layer;
(d) forming a conductor forming layer having a shape of a droplet by dropping a droplet of a conductive material on the semiconductor film; and
(e) forming a semiconductor layer of a thin film transistor section by processing the semiconductor film corresponding to the shape of the conductor forming layer.

31. The manufacturing method of a TFT array substrate as set forth in claim 30, further comprising the step of:
processing the conductor forming layer so as to form a conductor layer,
wherein:
the conductor layer is constituted of Mo, W, Ag, Cr, Ta, Ti, a metal material mainly containing one of Mo, W, Ag, Cr, Ta, Ti, or an indium tin oxide.

32. The manufacturing method of a TFT array substrate as set forth in claim 31, wherein:
the source and drain electrodes are made of an Al or a metal material mainly containing Al.

33. A manufacturing method of a liquid crystal display device including the manufacturing method of a TFT substrate as set forth in claim 30.

34. An electronic device including the TFT array substrate as set forth in claim 1.

35. An electronic device including the TFT array substrate as set forth in claim 26.
